(19) United States
(12) Patent Application Publication
(10) Pub. No.: US 2024/0423039 A1
(43) Pub. Date: Dec. 19, 2024

(54) LIGHT EMITTING DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); Sang Yong NO, Yongin-si (KR)

(73) Assignee: Samsung Display Co., LTD., Yongin-si (KR)

(21) Appl. No.: 18/596,294

(22) Filed: Mar. 5, 2024

(30) Foreign Application Priority Data
Jun. 15, 2023 (KR) 10-2023-0076847

(51) Int. Cl. H10K 59/131; H10K 59/121; H10K 59/123

(52) U.S. Cl. CPC H10K 59/131; H10K 59/1216; H10K 59/123

(57) ABSTRACT

A light emitting display device includes a unit pixel group including first, second, third, and fourth unit pixels arranged in a 2×2 matrix, and each of the first, second, third, and fourth unit pixel includes a first light emitting region, a second light emitting region, and a third light emitting region that emit lights of three primary colors, respectively, wherein the first, second, and third light emitting regions of the first light emitting region are sequentially in a first diagonal direction, the first, second, third, and fourth light emitting regions of the second unit pixel are sequentially arranged in a second diagonal direction, and the first, second, and third light emitting regions of the third unit pixel are sequentially arranged in a third diagonal direction, and the first, second, and third light emitting regions of the fourth unit pixel are sequentially arranged in a four diagonal direction.

### CROSS-REFERENCE TO RELATED APPLICATION(S)

This application claims priority to and benefits of Korean Patent Application No. 10-2023-0076847, filed on Jun. 15, 2023, at the Korean Intellectual Property Office, the entire contents of which are incorporated herein by reference.

### BACKGROUND

### 1. Technical Field

Embodiments relate to a light emitting display device.

### 2. Description of the Related Art

The display device is a device that displays a screen, and includes a liquid crystal display (LCD), an organic light emitting diode (OLED), and the like. Such display devices are used in various electronic devices such as mobile phones, navigation devices, digital cameras, electronic books, portable game consoles, and terminals. The organic light emitting display device has a self-luminance characteristic and, unlike a liquid crystal display device, does not require a separate light source, so the thickness and weight may be reduced. For example, the organic light emitting display device has high quality characteristics such as low power consumption, high luminance, and fast response speed.

### SUMMARY

Embodiments provide a light emitting display device including a space for a laser drilling process that performs electrical connection for transmitting voltage by using a laser.

Embodiments also provide a light emitting display device capable of preventing a color appearance phenomenon.

Embodiments also provide a light emitting display device having a high-resolution.

However, embodiments of the disclosure are not limited to those set forth herein. The above and other embodiments will become more apparent to one of ordinary skill in the art to which the disclosure pertains by referencing the detailed description of the disclosure given below.

The light emitting display device according to an embodiment may include a unit pixel group including first, second, third, and fourth unit pixels arranged in a 2×2 matrix shape in a first direction and a second direction that are perpendicular to each other, and each of the first, second, third, and fourth unit pixels may include a first light emitting region, a second light emitting region, and a third light emitting region that emit lights of three primary colors, respectively, the first light emitting region, the second light emitting region, and the third light emitting region of the first unit pixel may be arranged sequentially in a first diagonal direction with respect to the first and second directions, the first light emitting region, the second light emitting region, and the third light emitting region of the second unit pixel may be arranged sequentially in a second diagonal direction, the first light emitting region, the second light emitting region, and the third light emitting region of the third unit pixel may be arranged sequentially in a third diagonal direction, the first light emitting region, the second light emitting region, and the third light emitting region of the fourth unit pixel may be arranged sequentially in a fourth diagonal direction, the first diagonal direction, the second diagonal direction, the third diagonal direction, and the fourth diagonal direction may form a rhombus shape, and a position where a laser drilling process is performed in a center portion of the unit pixel group may be formed.

The second diagonal direction may be symmetrical to the first diagonal direction with respect to the second direction, and the third diagonal direction may be symmetrical to the first diagonal direction with respect to the first direction, and the fourth diagonal direction may be parallel to the first diagonal direction and may be opposite to the first diagonal direction.

A first virtual line may extend in the first diagonal direction and may diagonally connect corner portions of the first unit pixel, a second virtual line may extend in the second diagonal direction and may diagonally connect corner portions of the second unit pixel, a third virtual line may extend in the third diagonal direction and may diagonally connect corner portions of the third unit pixel, a fourth virtual line may extend in the fourth diagonal direction and may diagonally connect corner portions of the fourth unit pixel, and the first virtual line, the second virtual line, the third virtual line, and the fourth virtual line may form the rhombus shape.

The first light emitting region of the first unit pixel may be adjacent to the third light emitting region of the second unit pixel, the third light emitting region of the first unit pixel may be adjacent to the first light emitting region of the third unit pixel, the third light emitting region of the third unit pixel is adjacent to the first light emitting region of the fourth unit pixel, and the third light emitting region of the fourth unit pixel is adjacent to the first light emitting region of the second unit pixel.

The second unit pixel may be adjacent to the first unit pixel along the second direction, the third unit pixel may be adjacent to the first unit pixel along the first direction, and the fourth unit pixel may be adjacent to the first unit pixel in a diagonal direction.

A connecting electrode may be disposed at the center portion of the unit pixel group.

A pixel defining layer having openings corresponding to the first light emitting region, the second light emitting region, and the third light emitting region, an anode overlapping a portion of the opening of the pixel defining layer in plan view, a light emitting layer on the anode and disposed in the opening of the pixel defining layer, a cathode disposed on the pixel defining layer and the light emitting layer, and the connecting electrode may be electrically connected to the cathode by the laser drilling process.

The connecting electrode and the anode may be made of the same material and disposed on a same layer.

A low driving voltage line and an auxiliary low driving voltage line may be disposed on different insulating layers, and have different extension directions, the low driving voltage line and the auxiliary low driving voltage line may transfer the low driving voltage transferred to the cathode, and the connecting electrode may be electrically connected to the auxiliary low driving voltage line.

The light emitting display device according to an embodiment may include first, second, third, and fourth unit pixel groups arranged in a 2×2 matrix shape in a first direction and a second direction that are perpendicular to each other, and each of first, second, third, and fourth unit pixel groups may include first, second, third, and fourth unit pixels arranged in a 2×2 matrix shape, each of the first, second, third, and fourth unit pixels may include a first light emitting region, a second light emitting region, and a third light emitting region that emit lights of three primary colors, and a position for a laser drilling process may correspond to a position where corners of the four unit pixel groups meet, and positions where the laser drilling process is performed are in all of the first, second, third, and fourth unit pixel groups.

The first light emitting region, the second light emitting region, and the third light emitting region of the first, second, third, and fourth unit pixels where the laser drilling process is performed may be arranged in a rhombus shape.

Each of first, second, third, and fourth unit pixel groups may include a first unit pixel, a second unit pixel, a third unit pixel, and a fourth unit pixel, wherein the first light emitting region, the second light emitting region, and the third light emitting region of the first unit pixel may be sequentially arranged in a first diagonal direction with respect to the first and second directions, and the first light emitting region, the second light emitting region, and the third light emitting region of the second unit pixel may be sequentially arranged in a second diagonal direction. The first light emitting region, the second light emitting region, and the third light emitting region of the third unit pixel may be sequentially arranged in a third diagonal direction. The first light emitting region, the second light emitting region, and the third light emitting region of the fourth unit pixel may be sequentially arranged in a fourth diagonal direction, and the first, second, and third diagonal directions may form a rhombus shape.

The second diagonal direction may be symmetrical to the first diagonal direction with respect to the second direction, and the third diagonal direction may be symmetrical to the first diagonal direction with respect to the first direction, and the fourth diagonal direction may be parallel to the first diagonal direction and opposite to the first diagonal direction.

A first virtual line may extend in the first diagonal direction and may diagonally connect corner portions of the first unit pixel, a second virtual line may extend in the second diagonal direction and may diagonally connect corner portions of the second unit pixel, a third virtual line may extend in the third diagonal direction and may diagonally connect corner portions of the third unit pixel, a fourth virtual line may extend in the fourth diagonal direction and may diagonally connect corner portions of the fourth unit pixel, and the first virtual line, the second virtual line, the third virtual line, and the fourth virtual line may form the rhombus shape.

The first light emitting region of the first unit pixel may be adjacent to the third light emitting region of the second unit pixel, the third light emitting region of the first unit pixel may be adjacent to the first light emitting region of the third unit pixel, the third light emitting region of the third unit pixel may be adjacent to the first light emitting region of the fourth unit pixel, and the third light emitting region of the fourth unit pixel may be adjacent to the first light emitting region of the second unit pixel.

The second unit pixel may be adjacent to the first unit pixel in the second direction, the third unit pixel may be adjacent to the first unit pixel in the first direction, and the fourth unit pixel may be adjacent to the first unit pixel in a diagonal direction.

A connecting electrode may be disposed where corner portions of the first, second, third, and fourth unit pixel groups meet.

A pixel defining layer having openings corresponding to the first light emitting region, the second light emitting region, and the third light emitting region, an anode overlapping a portion of the opening of the pixel defining layer in plan view, a light emitting layer on the anode and disposed in the opening of the pixel defining layer, and a cathode disposed on the pixel defining layer and the light emitting layer, wherein the connecting electrode may be electrically connected to the cathode by a laser drilling process, and the connecting electrode and the anode may be made of a same material and disposed on a same layer.

A low driving voltage line and an auxiliary low driving voltage line may be disposed on different insulating layers and have different extension directions. The low driving voltage line and the auxiliary low driving voltage line may transfer a low driving voltage to the cathode, and the connector may be electrically connected to the auxiliary low driving voltage line.

An additional connecting electrode may be disposed at the center portion of the unit pixel group, and the additional connecting electrode and the anode may be made of a same material and disposed on a same layer.

According to an embodiments, three-color light emitting regions or light emitting devices are sequentially arranged in one direction from four adjacent unit pixels, and can be arranged in a rhombus shape, enabling laser drilling in the center area of the rhombus shape even in a light emitting display device with a high number of pixels per inch.

According to embodiments, it is possible to prevent a color emergence phenomenon from occurring by arranging colors with changing the arrangement of colors in a plurality of unit pixels.

According to embodiments, a light emitting display device with high resolution may be provided by preventing a user from seeing a low resolution by preventing light emitting regions or light emitting devices of the same color from being disposed adjacent to each other in two adjacent unit pixels.

### BRIEF DESCRIPTION OF THE DRAWINGS

FIG. 1 is a schematic top plan view of a display area of a light emitting display device according to an embodiment.

FIG. 2 is a schematic plan view illustrating a light emitting device and a position for a laser drilling process in the light emitting display device according to the embodiment of FIG. 1.

FIG. 3 is a schematic cross-sectional view of the light emitting display device according to the embodiment of FIG. 1.

FIG. 4 is a schematic diagram of an equivalent circuit of a pixel of a light emitting display device according to an embodiment.

FIGS. 5, 6, 7, and 8 are schematic plan views illustrating positions of light emitting devices and a laser drilling process in a light emitting display device according to an embodiment.

FIG. 9 is a table comparing display characteristics according to an embodiment and a comparative example.

FIG. 10 is a schematic top plan view illustrating a light emitting device and a position for a laser drilling process according to an embodiment.

FIG. 11 is a schematic block diagram of an electronic device according to embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

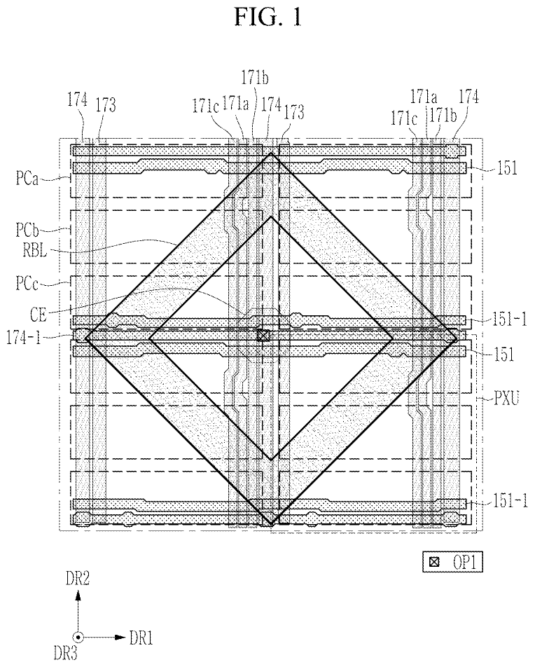

Hereinafter, the structure of the display area of the light emitting display device will be described in detail through drawings, and first, a schematic planar structure will be described referring to FIG. 1.

FIG. 1 is a schematic top plan view of a display area of a light emitting display device according to an embodiment. FIG. 1 illustrates a portion of the display area, and a pixel may include a light emitting device and a pixel driving unit.

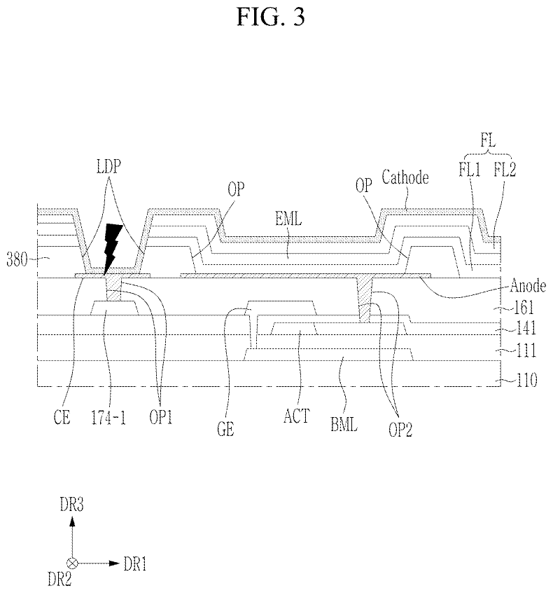

In FIG. 1, the arrangement of the light emitting devices (RBL; hereinafter referred to as arrangement of the light emitting device) may have a rhombus shape. For example, the light emitting device may correspond to a light emitting region on a planar structure, and the light emitting region may correspond to an opening disposed in the pixel defining layer (see 380 in FIG. 3) or a light emitting layer disposed in the opening (see EML in FIG. 3).

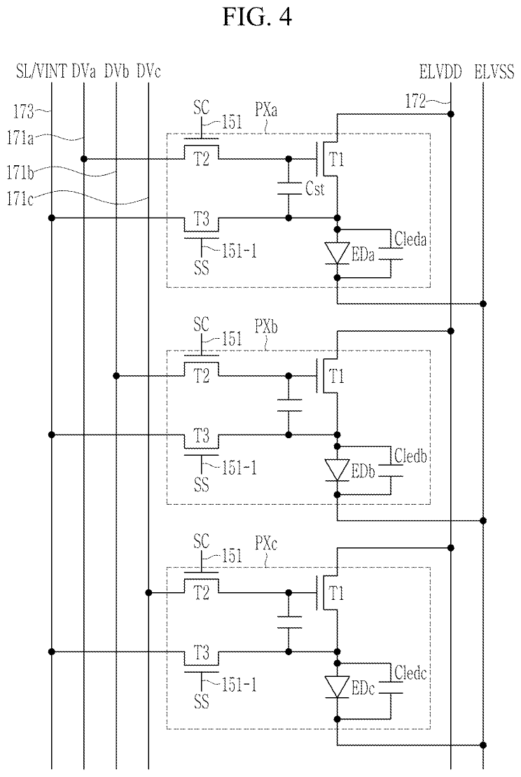

First, the structure of the pixel driving unit in FIG. I will be described below. In FIG. 1, a total of three pixel driving units PCa, PCb, and PCc adjacent to each other by dotted lines are schematically shown. The three pixel driving units PCa, PCb, and PCc each may form a pixel driving unit of a unit pixel PXU, and a total of four unit pixels PXUs may formed in a position. It is also called a unit pixel group, which includes four unit pixels PXUs. Each unit pixel PXU may include three pixels corresponding to the three primary colors. Three pixel driving units PCa, PCb, and PCc including in a single unit pixel PXU may have a structure that extends along the first direction DR1, and each of the three pixel driving units PCa, PCb, and PCc may be pixel driving units PCa, PCb, and PCc corresponding to pixels that display the three primary colors of light. The structure of the pixel driving unit PCa, PCb, and PCc may vary, and according to an embodiment, the structure of the pixel driving unit PCa, PCb, and PCc may have the same circuit structure as shown in FIG. 4.

In FIG. 1, some of the wiring connected to the pixel driving units PCa, PCb, and PCc may be additionally added. FIG. 1 illustrates a first scan signal line 151 and a second scan signal line 151-1 extending in the first direction DR1, and also data lines 171a, 171b, and 171c, a driving voltage line 172, an initialization voltage line 173, and a low driving voltage line (174; also referred to as the second driving voltage line) extending in the second direction DR2.

For example, the pixel driving units PCa, PCb, and PCc may be commonly connected to the first scan signal line 151, the second scan signal line 151-1, the driving voltage line 172, the initialization voltage line 173, and the low driving voltage line 174. For example, the first pixel driving unit PCa may be connected to the first data line 171a, the second pixel driving unit PCb may be connected to the second data line 171b, and the third pixel driving unit PCc may be connected to the third data line 171c. The pixel driving units PCa, PCb, and PCc may correspond to each divided region in three regions, which are partitioned by the first scan signal line 151, the second scan signal line 151-1, and the low driving voltage line 174.

FIG. 1 also illustrates an auxiliary low driving voltage line (174-1; hereinafter referred to as the auxiliary low driving voltage line) that extends in the first direction DR1. The auxiliary low driving voltage line 174-1 and the driving voltage line 174 may be disposed on different insulating layers and may extend in different directions. For example, the auxiliary low driving voltage line 174-1 may be connected to the low driving voltage line 174 that extends in the second direction DR2, and the low driving voltage ELVSS may be transmitted in the first direction DR1 and the second direction DR2 to be applied to a certain level of low driving voltage ELVSS over the entire display area of the light emitting display device. The low driving voltage ELVSS, which is supplied from an external low-voltage supply system, may be applied to the cathode of the light emitting device.

Referring to FIG. 3, the cathode may be disposed above the pixel defining layer (refer to 380 in FIG. 3), and may be disposed at the top in the third direction DR3. In an embodiment, a laser drilling process/method may be used to electrically connect the cathode and the auxiliary low driving voltage line 174-1. The laser drilling process/method may be a method in which the laser is used to melt a conductive material, which is formed under the cathode, such that the auxiliary low driving voltage line 174-1 disposed below may be electrically connected to the cathode. In the embodiment of FIG. 1, a connecting electrode CE may be formed between the auxiliary low driving voltage line 174-1 and the cathode, and may provide electrical connection between the auxiliary low driving voltage line 174-1 and the cathode. For example, in the embodiment of FIG. 1, the connecting electrode CE may be electrically connected to the auxiliary low driving voltage line 174-1 through the opening OP1. The connecting electrode CE may be electrically connected to the cathode through the laser drilling process. As a result, the cathode may receive the low driving voltage ELVSS through the auxiliary low driving voltage line 174-1. In the embodiments, the connecting electrode CE may correspond to the position where a laser drilling process is performed.

Although the position where a laser drilling process is performed overlaps the connecting electrode CE in plan view, the first scan signal line 151 and the second scan signal line 151-1 disposed underneath may be blocked by the connecting electrode CE during the laser drilling process and may prevent short-circuit with the connecting electrode CE, and the low driving voltage ELVSS may be prevented from being transmitted. Therefore, by using a connecting electrode CE, wiring may be formed on the lower part of the area where the laser drilling process is performed, such that the formation of wiring and components is performed in a narrow area, thereby improving integration.

Above the third direction DR3 of the pixel driving unit PCa, PCb, and PCc, a light emitting device (or a light emitting region) may be formed/disposed. Referring to FIG. 1, it is shown that multiple light emitting devices (or light emitting regions) included in four unit pixels PXU adjacent to each other in a 2×2 matrix structure may be disposed in a rhombus shape, as well as in arrangement of a light emitting device (RBL; also referred to as an arrangement of light emitting regions). For example, the rhombus shape may have 4 corners and 4 sides, e.g., various quadrangle shapes. In a rhombus shape, the angles formed by two adjacent sides may be either 90 degrees or acute angles less than 90 degrees, or obtuse angles greater than 90 degrees. Each side of a rhombus may have a diagonal direction that forms a certain angle with the first direction DR1 and/or the second direction DR2, in case that the diagonal direction of one side (hereinafter referred to as the first diagonal direction DDR1) is determined, the two adjacent sides may have symmetrical directions with respect to the first diagonal direction DDR1 as the reference for the first direction DR1 and the second direction DR2 respectively. For example, the remaining side may have a diagonal direction identical to or opposite to the first diagonal direction DDR1.

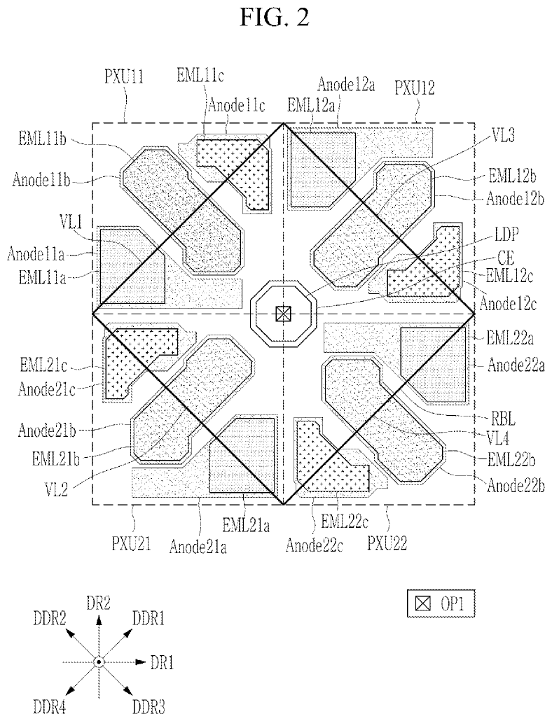

In the embodiment of FIG. 1, the light emitting devices (or light emitting regions) may be arranged in a rhombus shape with adjacent sides forming a 90-degree angle, according to the arrangement RBL of the light emitting device. The arrangement RBL of the light emitting device will be described through FIG. 2.

FIG. 2 is a plan showing the light emitting device and the position for the laser drilling process in the light emitting device according to the embodiment of FIG. 1. In FIG. 2, the approximate planar positions of the unit pixels PXU11, PXU12, PXU21, and PXU22 are shown with dotted lines.

The four unit pixels PXU11, PXU12, PXU21, and PXU22 disposed in FIG. 2 may form a unit pixel group. Above each of the three pixel driving units PCa, PCb, and PCc included in each unit pixel PXU11, PXU12, PXU21, and PXU22, three light emitting devices may disposed.

Referring to FIG. 1 and FIG. 2, a pixel defining layer (refer to 380 in FIG. 3) may be formed above the pixel driving units PCa, PCb, and PCc. The pixel defining layer may have openings exposing a portion of the anodes Anode11a, Anode12a, Anode21a, Anode22a, Anode11b, Anode12b, Anode21b, Anode22b, Anode11c, Anode12c, Anode21c, and/or Anode22c and cathodes that are part of the light emitting device. For example, each light emitting layer EML11a, EML12a, EML21a, EML22a, EML11b, EML12b, EML21b, EML22b, EML11c, EML12c, EML21c, and/or EML22c may be disposed in the openings OP of the pixel defining layer.

Each light emitting layer EML11a, EML12a, EML21a, EML22a, EML11b, EML12b, EML21b, EML22b, EML11c, EML12c, EML21c, and/or EML22c may be formed by an inkjet method, and may include at least one quantum dots material. The pixel defining layer and each light emitting layer EML11a, EML12a, EML21a, EML22a, EML11b, EML12b, EML21b, EML22b, EML11c, EML12c, EML21c, and/or EML22c may be covered with a cathode (refer to Cathode of FIG. 3). The first pixel driving unit PCa may be electrically connected to each first anode Anode11a, Anode12a, Anode21a, and Anode22a, and the second pixel driving unit PCb may be electrically connected to each second anode Anode11b, Anode12b, Anode21b, and Anode22b, and the third pixel driving unit PCc may be electrically connected to each third anode Anode11c, Anode12c, Anode21c, and Anode22c.

In FIG. 2, the structure connecting each anode Anode11a, Anode12a, Anode21a, Anode22a, Anode11b, Anode 12b, Anode21b, Anode22b, Anode11c, Anode12c, Anode21c, and/or Anode22c to each pixel driving unit PCa, PCb, and PCc is omitted, but in FIG. 3, it is possible to have a structure connecting the transistors of each pixel driving unit PCa, PCb, and PCc.

In the embodiments of FIG. 1 and FIG. 2, the first light emitting device may include a first anode Anode11a, Anode12a, Anode21a, and Anode22a, a first light emitting layer EML11a, EML12a, EML21a, and EML22a, and a cathode. The second light emitting device may include a second anode Anode11b, Anode12b, Anode21b, and Anode22b, a second light emitting layer EML11b, EML12b, EML21b, and EML22b, and a cathode. The third light emitting device may include a third anode Anode11c, Anode 12c, Anode21c, and Anode22c, a third light emitting layer EML11c, EML12c, EML21c, and EML22c, and a cathode. In FIG. 2, the cathode may be disposed across the entire region.

In FIG. 2, the luminous area corresponding to each light emitting device may refer to the area where the light emitting layer included in each light emitting device is disposed, or the area corresponding to the opening OP of the pixel defining layer (refer to 380 in FIG. 3). For example, the shapes of each light emitting layer EML11a, EML12a, EML21a, EML22a, EML11b, EML12b, EML21b, EML22b, EML11c, EML12c, EML21c, and/or EML22c as shown in FIG. 2 may correspond to the shapes of the openings OP of the pixel defining layer (refer to 380 of FIG. 3) and may correspond to the light emitting region.

The plane shape of each light emitting layer (or pixel defining layer 380 of FIG. 3) may have a polygon shape such as a triangle or a circular or elliptical shape, and according to an embodiment, the edges of the polygon may also have a serrated structure. The plane shape of each light emitting layer (or the opening OP of the pixel defining layer 380 of FIG. 3) according to the embodiment of FIG. 2 will be described later.

The planar shape of the opening OP of the pixel defining layer 380 of FIG. 3 corresponding to the first light emitting layer EML11a, EML12a, EML21a, and EML22a or the first light emitting layer EML11a, EML12a, EML21a, and EML22a may be a rectangle with at least one corner chamfered or may have a pentagon shape with chamfered corners. The planar shape of the opening OP of the pixel defining layer 380 of FIG. 3 corresponding to the second light emitting layer EML11b, EML12b, EML21b, and EML22b or the second light emitting layer EML11b, EML12b, EML21b, and EML22b may include a structure including a mosaic structure and a protrusion structure in a rectangular shape, or may include a portion extending in the second direction DR2 and a portion bent in a diagonal direction. For example, the corners thereof may be mosaic and may also include a protrusion structure.

The planar shape of the opening OP of the pixel defining layer 380 of FIG. 3 corresponding to the third light emitting layer EML11c, EML12c, EML21c, and EML22c may include a mosaic structure and a protrusion structure in a triangular structure, in the embodiment of FIG. 2, an edge of the triangular structure may be mosaic, and the two edges may include a protruded structure. For example, the first light emitting layer EML11a, EML12a, EML21a, and EML22a may display first color light, the second light emitting layer EML11b, EML12b, EML21b, and EML22b may display second color light, and the third light emitting layer EML11c, EML12c, EML21c, and EML22c may display third color light. The first, second, and third color lights may be lights of three primary colors.

The area of each light emitting layer EML11a, EML12a, EML21a, EML22a, EML11b, EML12b, EML21b, EML22b, EML11c, EML12c, EML21c, and/or EML22c may be variously formed, considering the lifespan of the materials of the light emitting layer. For example, the area ratio may vary in different ways in FIG. 2. The plane shape of each light emitting layer (or pixel defining layer 380 of FIG. 3) may vary according to the embodiment. For example, the arrangement of each light emitting layer (or pixel defining layer 380 of FIG. 3) may be varied. The planar shape of each light emitting layer (or the opening OP of the pixel defining layer 380 in FIG. 3) may vary, but the description describes the basic structure as shown in FIG. 2.

In FIG. 2, three light emitting layers (or light emitting regions) of a first unit pixel PXU11 may be sequentially arranged in a diagonal direction (also referred to as a first diagonal direction DDR1) extending between the first direction DR1 and the second direction DR2. For example, a second unit pixel PXU21 may be adjacent to the first unit pixel PXU11 along the second direction DR2, and may have three light emitting layers (or light emitting regions), which are arranged sequentially in another diagonal direction (also referred to a second diagonal direction DDR2) symmetrical to the first diagonal direction DDR1 with respect to the second direction DR2. For example, the three light emitting layers (or light emitting regions) of the second unit pixel PXU21 may be formed by rotating the three light emitting layers (or light emitting regions) of the first unit pixel PXU11 by about 90 degrees in the counter-clockwise direction and may be sequentially arranged along another diagonal direction (hereinafter referred to as the second diagonal direction DDR2). The second diagonal direction DDR2 may extend between the second direction DR2 and the opposite direction of the first direction DR1. For example, a third unit pixel PXU12 may be adjacent to the first unit pixel PXU11 in the first direction DR1. Three light emitting layers (or light emitting regions) of the third unit pixel PXU12 may be formed by rotating the three light emitting layers (or light emitting regions) of the first unit pixel PXU11 by about 90 degrees in the clockwise direction and may be sequentially arranged along another diagonal direction (hereinafter also referred to as the third diagonal direction DDR3). The third diagonal direction DDR3 may extend between the first direction DR1 and the opposite direction of the second direction DR2. For example, a fourth unit pixel PXU22 may be adjacent to the first unit pixel PXU11 in a diagonal direction. Three light emitting layers (or light emitting regions) of the fourth unit pixels PXU22 may be formed by rotating the three light emitting layers (or light emitting regions) of the first unit pixel PXU11 by about 180 degrees in the clockwise direction, and may be arranged sequentially along another diagonal direction (hereinafter referred to as the fourth diagonal direction DDR4) parallel to the first diagonal direction DDR1 but with an angle of 180 degrees. The fourth diagonal direction DDR4 may be opposite to the first diagonal direction DDR1 and may extend between the opposite direction of the first direction DR1 and the opposite direction of the second direction DR2.

According to the four diagonal directions DDR1, DDR2, DDR3, and DDR4 mentioned above, the arrangement RBL of light emitting devices may be arranged in a rhombus shape as shown in FIG. 2. In the above, the diagonal directions DDR1, DDR2, DDR3, and DDR4 may be the arrangement direction according to the order of the first light emitting layer EML11a, EML12a, EML21a, and EML22a, the second light emitting layer EML11b, EML12b, EML21b, and EML22b, and the third light emitting layer EML11c, EML12c, EML21c, and EML22c. By connecting the direction in which each light emitting layer is sequentially arranged in a unit pixel group consisting of four unit pixels in FIG. 2, the arrangement RBL of the light emitting device may rotate along the rhombus shape. For example, the arrangement RBL of the light emitting device may rotate in the shape of a rhombus by connecting the end portion of the first diagonal direction DDR1 and the front of the second diagonal direction DDR2, connecting the end portion of the second diagonal direction DDR2 and the front of the third diagonal direction DDR3, connecting the end portion of the third diagonal direction DDR3 and the front of the fourth diagonal direction DDR4, and sequentially connecting the end portion of the fourth diagonal direction DDR4 and the front of the first diagonal direction DDR1. Therefore, the light emitting layer or light emitting region displaying the same color may be arranged without being adjacent to each other. For example, a first virtual line VL1 may extend in the first diagonal direction DDR1 and may diagonally connect corner portions of the first unit pixel PXU11, a second virtual line VL2 may extend in the second diagonal direction DDR2 and may diagonally connect corner portions of the second unit pixel PXU21, a third virtual line VL3 may extend in the third diagonal direction DDR3 and may diagonally connect corner portions of the third unit pixel PXU12, and a fourth virtual line VL4 may extend in the fourth diagonal direction DDR4 and may diagonally connect corner portions of the fourth unit pixel PXU22. The first virtual line VL1, the second virtual line VL2, the third virtual line VL3, and the fourth virtual line VL4 may form the rhombus shape.

The arrangement of the light emitting layer (or the opening OP of the pixel defining layer 380 of FIG. 3) in a single unit pixel group consisting of four unit pixels PXU11, PXU12, PXU21, and PXU22 of FIG. 2 will be described later.

First, each light emitting layer EML11a, EML11b, and EML11c of the first unit pixel PXU11 may be arranged in the first diagonal direction DDR1 between the first direction DR1 and the second direction DR2. For example, in the area of the first unit pixel PXU11 of FIG. 2, the first light emitting layer EML11a may be disposed in the lower left area, the second light emitting layer EML11b may be disposed in the middle area, and the third light emitting layer EML11c may be disposed in the upper right area.

The emitting layers EML21a, EML21b, and EML21c of the second pixels PXU21 may be arranged in the second diagonal direction DDR2 between the opposite direction of the first direction DR1 and the second direction DR2, and EML21c. For example, in the area of the second unit pixel PXU21 of FIG. 2, the first light emitting layer EML21a may be disposed in the lower right area, the second light emitting layer EML21b may be disposed in the middle area, and the third light emitting layer EML21c may be disposed in the upper left area.

In FIG. 2, the third unit pixel PXU12 may be adjacent to the first unit pixel PXU11 in the first direction DR1. Each light emitting layer EML12a, EML12b, and EML12c of the third pixel PXU12 may be arranged in the diagonal direction (e.g., third diagonal direction DDR3) between the first direction DR1 and the opposite direction of the second direction DR2. For example, in the region of the third unit pixel PXU12 of FIG. 2, the first light emitting layer EML12a may be disposed in the upper left area, the second light emitting layer EML12b may be disposed in the middle area, and the third light emitting layer EML12c may be disposed in the lower right area.

In FIG. 2, the fourth unit pixel PXU22 may be adjacent to the first unit pixel PXU11 along a diagonal direction. Each light emitting layer EML22a, EML22b, and EML22c of a fourth unit pixel PXU22 may be arranged in the fourth diagonal direction DDR4, which is the direction between the opposite direction of the first direction DR1 and the opposite direction of the second direction DR2.

For example, in the area of the fourth unit pixel PXU22 of FIG. 2, the first light emitting layer EML22a may be disposed in the upper right area, the second light emitting layer EML22b may be disposed in the middle area, and the third light emitting layer EML22c may be disposed in the lower left area. In FIG. 2, the fourth unit pixel PXU22 may be a unit pixel that is disposed adjacent to the first unit pixel PXU11 in the diagonal direction. Therefore, by connecting the four diagonal directions DDR1, DDR2, DDR3, and DDR4 in a unit pixel group including four unit pixels PXU11, PXU12, PXU21, and PXU22, the unit pixel group may have a rhombus shape like arrangement RBL of a light emitting device.

For example, each light emitting layer EML11a, EML12a, EML21a, EML22a, EML11b, EML12b, EML21b, EML22b, EML11c, EML12c, EML21c, and/or EML22c included in each unit pixel PXU11, PXU12, PXU21, and PXU22 may be disposed in the center portion of the rhombus shape shown in FIG. 1. As described above, in each unit pixel, a light emitting layer or light emitting region may be arranged in four different diagonal directions, and in case that the four diagonal directions in a unit pixel group may be connected to form a diamond structure, the arrangement RBL of light emitting devices may have a diamond structure, or it may be referred to as multiple light emitting layers or light emitting regions arranged in a rhombus shape.

For example, in FIG. 2, a position LDP where the laser drilling process is performed may be also provided, and an opening OP1 may be also provided to connect the underlying connecting electrode CE and the underlying auxiliary low driving voltage line (refer to 174-1 of FIG. 1) electrically by overlapping the connecting electrode CE.

A laser drilling process may electrically connect the connecting electrode CE and the cathode, which is overall formed, by melting the insulating layer disposed between the connecting electrode CE and the cathode by a laser. However, in case that the area of the melting part, which is caused by the laser, is wide, and in case that the laser is irradiated to the anode or other conductive materials, a short-circuit may occur, thereby causing a malfunction of the pixel. Therefore, there is a need to allocate a certain area for a laser drilling process. In FIG. 2, multiple light emitting layers (or openings OP of a pixel defining layer, see reference numeral 380 of FIG. 3) may have a rhombus shape arrangement, so that a sufficient space for the laser drilling process may be provided in the central part. Thus, improper/defective short-circuits may be prevented by precisely arranging/overlapping the connecting electrodes CE and the position LDP for the laser drilling process.

In unit pixel groups, the connecting electrode CE and the position LDP for the laser drilling process in FIG. 2 may be formed around the corner portions where all unit pixels PXU11, PXU12, PXU21, and PXU22 meet, and the connecting electrode CE and the position LDP for the laser drilling process may be formed across all unit pixels PXU11, PXU12, PXU21, and PXU22. Therefore, in the embodiment of FIG. 2, in case that the connecting electrode CE and the position LDP for the laser drilling process require a certain area, it is only necessary to form ¼ of the corresponding area for each unit pixel PXU11, PXU12, PXU21, and PXU22, so the laser drilling process may be performed even in high-resolution display devices or high-pixel density display devices. Furthermore, the position LDP for the laser drilling process may be formed in a position that does not overlap each light emitting layer, anode, and/or light emitting region, such that the light emitting device may not be damaged during the laser drilling process.

The cross-sectional structure of the light-emitting display device with the same plane shape as above is described referring to FIG. 3. FIG. 3 is a schematic cross-sectional view of a light emitting display device according to the embodiment of FIG. 1.

The layer corresponding to the anode in the OLED device may be called the light emitting device layer, which includes the cathode Cathode, the pixel defining layer 380, the functional layer FL, and the light emitting layer EML in the cross-sectional view of FIG. 3. The charge layer, the semiconductor layer, and the insulation layer as a drive component layer may form the transistor and the capacitor. For example, a luminescent device may be disposed in the light emitting layer.

In FIG. 3, one of the first light emitting devices, the second light emitting device, and the third light emitting device is illustrated, and an opening OP disposed on the pixel defining layer 380 to expose a part of the anode is illustrated, and an opening OP2 through which current is transmitted from a transistor in the pixel driving unit PCa, PCb, and PCc to the anode is illustrated.

For example, in FIG. 3, a position LDP where the laser drilling process is performed may be schematically shown. In FIG. 3, the structure of the lower part of the anode, e.g., the structure of the driving component layer, is illustrated, with only one transistor depicted. A brief examination of the structure of the driving component layer from the substrate 110 to the interlayer insulating layer 161 is as follows.

The substrate 110 may include a material that is not bendable, such as glass, or a flexible material that is bendable, such as plastic or polyimide. In the case of a flexible substrate, the substrate 110 may have a dual-layer structure with a polyimide layer and a barrier layer formed on top thereof by using inorganic insulating materials.

A lower shielding layer BML including metal may be formed on the substrate 110. The lower shielding layer BML may overlap one of the transistors' channels and planes disposed in the pixel driving units PCa, PCb, and PCc included in the pixel. According to an embodiment, the lower shielding layer BML and an auxiliary low driving voltage line (refer to 174 of FIG. 1), which applies a low driving voltage ELVSS, may be disposed on the same layer.

The substrate 110 and the lower shielding layer BML may be covered by a buffer layer 111. The buffer layer 111 may function a role of blocking the infiltration (or permeation) of impurities into the semiconductor layer ACT, and may be an inorganic insulating layer including silicon oxide (SiOₓ), silicon nitride (SiNₓ), or silicon oxynitride (SiONₓ). A semiconductor layer ACT formed of silicon semiconductors (e.g., polycrystalline silicon) or oxide semiconductors may be formed on the buffer layer 111. The semiconductor layer ACT may be a semiconductor layer disposed in the pixel driving units PCa, PCb, and PCc included in the pixels. The semiconductor layer ACT may include the channel of the transistor (e.g., the driving transistor) and the first and second regions disposed on sides (e.g., opposite sides) of the channel. For example, the channel of the transistor may be the portion that overlaps the gate electrode GE in the semiconductor layer ACT, and the first region and the second region may be the portions of the semiconductor layer ACT that do not overlap the gate electrode GE. For example, the first region and the second region disposed on the sides (e.g., opposite sides) of the semiconductor layer ACT may perform the role of the first electrode and the second electrode of the transistor. The first region and the second region may not be covered by the gate electrode GE and may have the characteristics resulted by a doping process or a plasma treatment.

A first gate insulating layer 141 may be formed on the semiconductor layer ACT. The first gate insulating layer 141 may be an inorganic insulating layer including silicon oxide (SiOₓ), silicon nitride (SiNₓ), silicon oxynitride (SiONₓ), etc.

A first gate conductive layer may include a gate electrode GE of a transistor disposed on a pixel driving unit PCa, PCb, and PCc, and may be disposed above the first gate insulating layer 141. An auxiliary low driving voltage line 174-1 may be disposed in the first gate conductive layer, and a scan line may be formed in addition to the gate electrode GE of the transistor disposed in the pixel driving unit PCa, PCb, and PCc. For example, the first gate conductive layer may include a pixel driving unit PCa, PCb, and PCc and a first electrode of a capacitor disposed in the pixel driving unit. The first gate conductive layer may include metals or metal alloys such as aluminum (Al), copper (Cu), molybdenum (Mo), or titanium (Ti), and may be formed of a single layer or multiple layers.

After forming the first gate conductive layer, the plasma treatment or doping process may be performed to make the exposed area of the first semiconductor layer conductive. For example, the semiconductor layer ACT covered by the gate electrode GE may not be conductive, and the portion of the semiconductor layer ACT not covered by the gate electrode GE may have the same characteristics as the conductive layer.

An interlayer insulating layer 161 may be disposed above the first gate conductive layer and the first gate insulating layer 141. The interlayer insulating layer 161 may include an inorganic insulation layer including silicon oxide (SiOₓ), silicon nitride (SiNₓ), silicon oxynitride (SiONₓ), and the like, and according to an embodiment, it is possible to form a thick inorganic insulation material. For example, According to an embodiment, the interlayer insulating layer 161 may be formed as an organic insulation layer, and may include one or more materials selected from polyimide, polyamide, acrylic resin, benzocyclobutene, and phenolic resin.

An anode layer including an anode Anode and a connecting electrode CE may be disposed on the interlayer insulating layer 161. The anode Anode may be the first layer of the semiconductor layer ACT functioning as the second electrode of the transistor through an opening (OP2; hereinafter referred to as an anode opening) disposed in the interlayer insulating layer 161 and the first gate insulating layer 141, and the anode Anode may be connected to the second region of the semiconductor layer ACT. As a result, the anode may receive the output of the transistor.

The connecting electrode CE may be formed of the same material as the anode Anode and may be connected to the auxiliary low driving voltage line 174-1 through an opening OP1 disposed in the interlayer insulating layer 161, such as the opening for the laser drilling process. As a result, the connecting electrode CE may receive the low driving voltage ELVSS.

The anode layer may be formed of a single layer or multiple layers including transparent conductive oxide layers or metallic materials. Transparent conductive oxide layers may include indium tin oxide (ITO), poly-ITO, indium zinc oxide (IZO), indium gallium zinc oxide (IGZO), and indium tin zinc oxide (ITZO). Metal materials may include silver (Ag), molybdenum (Mo), copper (Cu), gold (Au), and aluminum (Al).

A pixel defining layer 380, which includes an opening OP, may be disposed above the anode layer. The opening OP of the pixel defining layer 380, such as the light emitting device opening, corresponds to the light emitting region and/or the light emitting layer EML, exposing a portion of the anode Anode, and the opening OP of the pixel defining layer 380 may have tapered sidewalls.

A light emitting layer EML may be disposed in the opening OP of the pixel defining layer 380, and according to an example, the light emitting layer EML may also be disposed on the pixel defining layer 380 as shown in FIG. 3. The light emitting layer EML may be formed by an inkjet method, and according to an embodiment, the light emitting layer EML may include at least one quantum dots material. In case of forming a light emitting layer EML by an inkjet method, the pixel defining layer 380 may perform the role of partitioning/separating the injected liquid. For example, the light emitting layer EML may only be disposed in the opening OP of the pixel defining layer 380.

The light emitting layer EML may include quantum dots materials, and according to an embodiment, a color conversion layer including quantum dots materials may be separately disposed above the cathode Cathode. In the description, quantum dots may be the crystals of semiconductor compounds and may include any material that emits light of various wavelengths according to the size of the crystals or the control of the element consumption in the quantum dots compounds. For example, the diameter of a quantum dots may have a range of about 1 nm to about 10 nm.

Quantum dots may be synthesized by wet chemical processes, organic metal chemical deposition processes, molecular beam epitaxy processes, or similar processes. The wet chemistry process may be a method of growing quantum dots particles by mixing organic solvents and precursor materials. In case that the crystal grows, the organic solvent may naturally function the role of a dispersing agent that is deposited on the surface of the quantum dots crystals, and it controls the growth of the crystals. Therefore, the growth of quantum dots particles may be readily controlled and may be performed at the lower cost by processes such as metal organic chemical vapor deposition (MOCVD) or molecular beam epitaxy (MBE) than atmospheric deposition methods.

Quantum dots may include compounds of group III-VI semiconductors, group II-VI semiconductors, group III-V semiconductors, group III-VI semiconductors, group I-III-VI semiconductors, group IV-VI semiconductors, group IV elements or compounds, or any combination thereof.

Examples of group II-VI semiconductor compounds may include binary clement compounds such as CdS, CdSe, CdTe, ZnS, ZnSe, ZnTe, ZnO, HgS, HgSe, HgTe, MgSe, MgS, and the like; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; quaternary compounds such as CdZnSeS, CdZnSeTe, CdZnSTe, CdHgSeS, CdHgSeTe, CdHgSTe, HgZnSeS, HgZnSeTe, HgZnSTe and the like; or any combination thereof.

Examples of group III-V semiconductor compounds may include binary element compounds such as GaN, GaP, GaAs, GaSb, AlN, AlP, AlAs, AlSb, InN, InP, InAs, InSb, and the like; ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and the like; quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and the like; or any combination thereof. For example, the group III-V semiconductor compound may further include a group II element. Examples of the group III-V semiconductor compound may further include a group II element such as InZnP, InGaZnP, InAlZnP, and the like.

Examples of group III-VI semiconductor compounds may include binary element compounds such as GaS, Ga₂S₃, GaSe, Ga₂Se₃, GaTe, InS, InSe, In₂Se₃, InTe and the like; ternary compounds such as InGaS₃ and InGaSe₃; or any combination thereof.

Examples of the group I-III-VI semiconductor compound may include ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂ and the like; quaternary compounds such as AgInGaS₂ and AgInGaSe₂; or any combination thereof.

Examples of group IV-VI semiconductor compounds may include binary element compounds such as SnS, SnSe, SnTe, PbS, PbSe, PbTe and the like; ternary compounds such as SnSeS, SnSeTe, SnSTe, PbSeS, PbSeTe, PbSTe, SnPbS, SnPbSe, SnPbTe and the like; quaternary compounds such as SnPbSSe, SnPbSeTe, and SnPbSTe; or any combination thereof.

Group IV elements or compounds may include single-element compounds such as Si, Ge, and the like; binary element compounds such as SiC, SiGe, and the like; or any combination thereof.

Each element included in a multi-element compound such as a binary element compound, a ternary element compound, and a quaternary element compound may be included in a particle at a uniform concentration or a non-uniform concentration. For example, the chemical formula means the types of elements included in the compound, and the element ratios in the compound may be different. For example, AgInGaS₂ may mean AgInₓGa₁₋ₓS₂. Here, x may be a real number between 0 and 1. For example, the quantum dots may have a single structure in which the concentration of each element included in the quantum dots is uniform or a dual core-shell structure.

For example, a material included in the core and a material included in the shell may be different from each other. The shell of the quantum dots may function as a protective layer for maintaining semiconductor properties by preventing chemical denaturation of the core and/or as a charging layer for imparting electrophoretic properties to the quantum dots. The shell may be a monolayer or a multilayer. The interface between the core and the shell may have a concentration gradient in which the concentration of elements included in the shell decreases toward the center.

Examples of the quantum dots shell may include oxides of metals or non-metals, semiconductor compounds, or combinations thereof. Examples of oxides of metals or nonmetals include binary element compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like; ternary compounds such as MgAl₂O₄, CoFe₂O₄, NiFe₂O₄, CoMn₂O₄ and the like; or any combination thereof. Examples of semiconductor compounds may include group III-VI semiconductor compounds, as described herein; group II-VI semiconductor compounds; group III-V semiconductor compounds; group III-VI semiconductor compounds; group I-III-VI semiconductor compounds; group IV-VI semiconductor compounds; or any combination thereof. For example, the semiconductor compound may be CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or any combination thereof.

Each element included in a multi-element compound such as a two-element compound or a three-element compound may be included in a particle at a uniform or non-uniform concentration. For example, the chemical formula means the types of elements included in the compound, and the element ratios in the compound may be different.

Quantum dots may have a full width of half maximum (FWHM) of an emission wavelength spectrum of about 45 nm or less, e.g., about 40 nm or less, e.g., about 30 nm or less, and color purity or color reproducibility may be improved in this range. For example, since light emitted through the quantum dots is emitted in all directions, a wide viewing angle may be improved.

For example, the shape of the quantum dots may be in the form of spherical, pyramidal, multi-arm, or cubic nanoparticles, nanotubes, nanowires, nanofibers, nanoplatelet particles, and the like. Since the energy band gap is controlled by adjusting the size of the quantum dots or the ratio of elements in the quantum dots compound, light of various wavelengths may be generated from the quantum dots light emitting layer.

Therefore, by using quantum dots as described above (by using quantum dots of different sizes or having different element ratios in a quantum dots compound), a light emitting device emitting light of various wavelengths may be implemented. For example, control of the size of the quantum dots or the ratio of elements in the quantum dots compound may be selected to emit red light, green light and/or blue light. For example, the quantum dots may be configured to emit white light by combining light of various colors.

For example, a first functional layer FL1 may be disposed between the anode Anode and the light emitting layer EML, and a second functional layer FL2 may be disposed above the light emitting layer EML. For example, the first functional layer FL1 may include a charge injection layer and/or a charge transfer layer, and the second functional layer FL2 may include an electron transfer layer and/or an electron injection layer. For example, the combination of the functional layer FL and the light emitting layer EML may be referred to as the intermediate layer. The first functional layer FL1 and the second functional layer FL2 may be also formed in the pixel defining layer 380 and the opening OP. Therefore, in the embodiment of FIG. 3, all of the intermediate layers may be disposed in the upper portion and the opening OP of the pixel defining layer 380. However, according to an embodiment, the light emitting layer EML may only be disposed in the opening OP of the pixel defining layer 380, although the functional layer FL also is formed above the pixel defining layer 380 and in the opening OP.

A cathode Cathode formed on the pixel defining layer 380 and the opening OP may be disposed above the second functional layer FL2. The anode Anode, the light emitting layer EML, and the cathode Cathode may form the light emitting device, and the light emitting device may include a functional layer FL. The current transmitted through the anode Anode may be transferred through the first functional layer FL1, the light emitting layer EML, and the second functional layer FL2 to the cathode Cathode. Thus, the light emitting layer EML may emit light due to the current flowing through it, and the first light emitting device may control the brightness.

Referring to FIG. 3, the cathode Cathode may be connected to the connecting electrode CE at the position LDP where the laser drilling process is performed, and may receive the low driving voltage ELVSS from the auxiliary low driving voltage line 174-1 through the connecting electrode CE. In FIG. 3, the cross-sectional structure of the position LDP where the laser drilling process is performed may be illustrated, and the cathode Cathode, the functional layer FL, and the light emitting layer EML may be connected to the underlying connecting electrode CE through clean openings OP of the pixel defining layer 380. However, due to the melting of the intermediate layer and the pixel defining layer 380 by the laser, the cathode Cathode and the connecting electrode CE may be electrically connected, resulting in a less-clean cross-sectional structure as compared to FIG. 3.

For example, according to an embodiment, a spacer may be further formed on the pixel defining layer 380, and the spacer may have tapered sidewalls similar to the pixel defining layer 380. For example, an encapsulation layer may be disposed according to an embodiment. The encapsulation layer may include at least one inorganic layer and at least one organic layer, and may have a triple layer-structure including a first inorganic encapsulation layer, an organic encapsulation layer, and a second inorganic encapsulation layer. The encapsulation layer may protect the light emitting layer EML from moisture or oxygen permeated from the outside. According to an embodiment, the encapsulation layer may include a structure in which an inorganic layer and an organic layer are sequentially stacked.

According to an embodiment, a sensing insulation layer and sensing electrodes may be disposed on the encapsulation layer for touch sensing.

According to an embodiment, a film including a polarizing plate may be attached to the encapsulation layer to reduce reflection of external light. For example, a color filter or a color conversion layer may be further formed to improve color quality, and a polarizing plate may not be attached. A light blocking layer may be disposed between the color filters or the color conversion layer. For example, according to an embodiment, a layer having a material capable of absorbing some wavelengths of external light (hereinafter referred to as a reflection adjusting material) may be further included, and a polarizing plate may not be attached. For example, according to an embodiment, the front surface of the light emitting display device may be flattened by covering it with an additional organic layer (also referred to as a planarization layer).

FIG. 3 is a cross-sectional structure according to an embodiment, and various deformable structures may be possible. Hereinafter, a circuit structure of a pixel included in the light emitting display device will be described referring to FIG. 4.

FIG. 4 is a schematic diagram of an equivalent circuit of a pixel of a light emitting display device according to an embodiment. In FIG. 4, the circuit diagram of three pixels PXa, PXb, and PXc is shown.

Multiple pixels may include the first pixel PXa, the second pixel PXb, and the third pixel PXc. The first pixel PXa, the second pixel PXb, and the third pixel PXc may each include multiple transistors T1, T2, and T3, a storage capacitor Cst, and a light emitting device EDa, EDb, and EDc. For example, each pixel PXa, PXb, and PXc may be distinguished by the light emitting device EDa, EDb, and EDc and the pixel driving unit PCa, PCb, and PCc, and the pixel driving unit PCa, PCb, and PCc may correspond to the portion indicated by the dashed line in FIG. 1.

Referring to FIG. 4, the pixel driving unit PCa, PCb, and PCc may include multiple transistors T1, T2, and T3 and a storage capacitor Cst corresponding to parts excluding the light emitting device EDa, EDb, and EDc from each pixel PXa, PXb, and PXc. For example, according to an embodiment, it is possible to include capacitors (Cleda, Cledb, and Cledc; hereinafter referred to as light emitting capacitors) connected to end portions (e.g., opposite end portions) of the light emitting devices EDa, EDb, and EDc, and the light emitting capacitors Cleda, Cledb, and Cledc may not be included in the pixel driving unit PCa, PCb, and PCc, and may be included in the light emitting devices EDa, EDb, and EDc.

Multiple transistors T1, T2, and T3 may be formed by a single driving transistor (T1; also such as the first transistor) and two switching transistors T2 and T3, with the two switching transistors being distinguished as the input transistor (T2; also such as the second transistor), and the initialization transistor (T3; also such as the third transistor). Each transistor T1, T2, and T3 may include a gate electrode, a first electrode, and a second electrode, and also may include a semiconductor layer including a channel. Thus, current may flow or be blocked in the channel of the semiconductor layer according to the voltage of the gate electrode. For example, the first electrode and the second electrode may be either the source electrode or the drain electrode according to the voltage applied to each transistor T1, T2, and T3. The gate electrode of the driving transistor TI may be connected to an end portion of the storage capacitor Cst, and it is also connected to the second electrode (e.g., output side electrode) of the input transistor T2.

Furthermore, the first electrode of the driving transistor T1 may be connected to the driving voltage line 172 that transfers the driving voltage ELVDD, and the second electrode of the driving transistor T1 may be connected to the anode Anode of the light emitting device EDa, EDb, and EDc, the discharge terminal of the storage capacitor Cst, the first electrode of the initialization transistor T3, and an end portion of the light emitting capacitors Cleda, Cledb, and Cledc. The driving transistor T1 may receive the data voltage DVa, DVb, and DVc through the switching operation of the input transistor T2 and may supply driving current to the light emitting device EDa, EDb, and EDc according to the voltage of the gate electrode. Thus, the storage capacitor Cst may store and may maintain the voltage of the gate electrode of the driving transistor T1.

The gate electrode of the input transistor T2 may be connected to the first scan signal line 151 that transmits the first scan signal SC. The first electrode of the input transistor T2 may be connected to the data lines 171a, 171b, and 171c that transmit the data voltage DVa, DVb, and DVc, and the second electrode of the input transistor T2 may be connected to the first electrode of the storage capacitor Cst and the gate electrode of the driving transistor T1.

The multiple data lines 171a, 171b, and 171c may transmit different data voltages DVa, DVb, and DVc respectively, and the input transistor T2 of each pixel PXa, PXb, and PXc may be connected to different data lines 171a, 171b, and 171c. The gate electrodes of the input transistors T2 of each pixel PXa, PXb, and PXc may be connected to the same first scan signal line 151, so they may receive the first scan signal SC at the same timing. The input transistors T2 of each pixel PXa, PXb, and PXc may be turned on simultaneously by the first scan signal SC at the same timing, but different data voltages DVa, DVb, and DVc may be transmitted to the gate electrode of the driving transistor T1 and the storage capacitor Cst of each pixel PXa, PXb, and PXc through different data lines 171a, 171b, and 171c.

FIG. 4 is an embodiment where the gate electrode of the initialization transistor T3 receives a different scan signal from the gate electrode of the input transistor T2.

The gate electrode of the initialization transistor T3 may be connected to the second scan signal line 151-1 that transmits the second scan signal SS. The first electrode of the initialization transistor T3 may be connected to the cathode of the storage capacitor Cst, the second electrode of the driving transistor T1, the anode Anode of the light emitting device EDa, EDb, and EDc, and the cathode of the light emitting capacitor Cleda, Cledb, and Cledc. The second electrode of the initialization transistor T3 may be connected to the initialization voltage line 173 that transfers the initialization voltage VINT. The initialization transistor T3 may turn on according to the second scan signal SS and may transfer the initialization voltage VINT to the anodes of the light emitting devices EDa, EDb, and EDc, the cathodes of the light emitting capacitors Cleda, Cledb, and Cledc, and the terminal of the storage capacitor Cst to reset the voltage of the anodes of the light emitting devices EDa, EDb, and EDc.

The initialization voltage line 173 may also perform the function of detecting the voltage of the anode of the light emitting element EDa, EDb, and EDc before applying the initialization voltage VINT and performing the operation to the detection wiring SL. Through the sensing operation, it may be confirmed whether the voltage of the first anode is maintained at the target voltage. The sensing operation and the initialization operation of transmitting the initialization voltage VINT may be separated in time, and the initialization operation may be performed after the sensing operation is performed.

In the embodiment of FIG. 4, since the turn-on period of the initialization transistor T3 and the input transistor T2 are distinguished, the writing operation performed by the input transistor T2 and the initialization operation performed by the initialization transistor T3 (and/or sensing operation) may be performed at different times.

The first end portion of the storage capacitor Cst may be connected to the gate electrode of the driving transistor T1 and the second electrode of the input transistor T2, and another end portion of the storage capacitor Cst may be connected to the first electrode of the initialization transistor T3, the second electrode of the driving transistor T1, the anode of the light emitting device EDa, EDb, or EDc, and the first end portion of the light emitting capacitor Cleda, Cledb, or Cledc.

The light emitting devices EDa, EDb, and EDc may receive the output current of the driving transistor T1 through the anode, and the cathodes of the light emitting devices EDa, EDb, and EDc may receive the low driving voltage ELVSS through the auxiliary low driving voltage line 174-1. The light emitting devices EDa, EDb, and EDc may emit light according to the output current of the driving transistor T1.

For example, light emitting capacitors Cleda, Cledb, and Cledc may be formed at end portions (e.g., opposite end portions) of the light emitting devices EDa, EDb, and EDc so that the voltage across the light emitting devices EDa, EDb, and EDc may be kept constant. Thus, the light emitting devices EDa, EDb, and EDc may display constant luminance.

Hereinafter, an operation of a pixel having a circuit as shown in FIG. 4 will be described.

In FIG. 4, each of the transistors T1, T2, and T3 may be an N-type transistor, and may be turned on in case that a high-level voltage is applied to the gate electrode. However, according to embodiments, each of the transistors T1, T2, and T3 may be a P-type transistor.

In case that the emission period ends, a frame may begin. After that, the high-level second scan signal SS may be supplied to turn on the initialization transistor T3. In case that the initialization transistor T3 is turned on, an initialization operation and/or a sensing operation may be performed.

An embodiment in which both an initialization operation and a detection operation are performed will be described below.

The sensing operation may be performed before the initialization operation is performed. For example, in case that the initialization transistor T3 is turned on, the initialization voltage line 173 may perform the role of the detection wiring SL to detect the voltage of the anode of the light emitting device EDa, EDb, and EDc. Through the detection operation, it may be detected whether the voltage of the anode is maintained at the target voltage.

After that, the initialization operation may be performed, and the voltage of the storage capacitor Cst, the second electrode of the driving transistor T1, and the anode of the light emitting device EDa, EDb, and EDc may be changed to the initialization voltage VINT transmitted from the initialization voltage line 173 to perform initialization.

As described above, the sensing operation and the initialization operation of transmitting the initialization voltage VINT may be separated in time, so that the pixel may perform various operations with using a minimum number of transistors and reducing the area occupied by the pixel. As a result, resolution of the display panel may be improved.

With the initialization operation or at a separate timing, the first scan signal SC may be changed to a high level, and the input transistor T2 may be turned on, and the input operation may be performed. For example, the data voltage DVa, DVb, and DVc from the data lines 171a, 171b, and 171c may be input and stored at an end portion of the gate electrode of the driving transistor T1 and the storage capacitor Cst through the turned-on input transistor T2. The data voltages DVa, DVb, and DVc and the initialization voltage VINT may be applied to end portions (e.g., opposite end portions) of the storage capacitor Cst by the initialization operation and the writing operation.

In case that the initialization transistor T3 is turned on, in case that the output current is generated from the driving transistor T1, the output current may be output to the outside through the initialization transistor T3 and the initialization voltage line 173, so the output current may not be input to the anode of the light emitting device EDa, EDb, and EDc.

For example, during the input period where a first scan signal SC having a high-level voltage is supplied, the driving voltage ELVDD may be applied as a low-level voltage, or the low driving voltage ELVSS may be applied as a high-level voltage to prevent current from flowing through the light emitting devices EDa, EDb, and EDc. Afterwards, in case that the first scan signal SC is changed to a low level, the driving transistor T1 may generate and output an output current based on the high-level driving voltage ELVDD applied to the driving transistor T1 and the gate voltage of the driving transistor T1 stored in the storage capacitor Cst. The output current of the driving transistor T1 may be input to the light emitting devices EDa, EDb, and EDc, and a light emitting operation may be performed where the light emitting devices EDa, EDb, and EDc emit light.

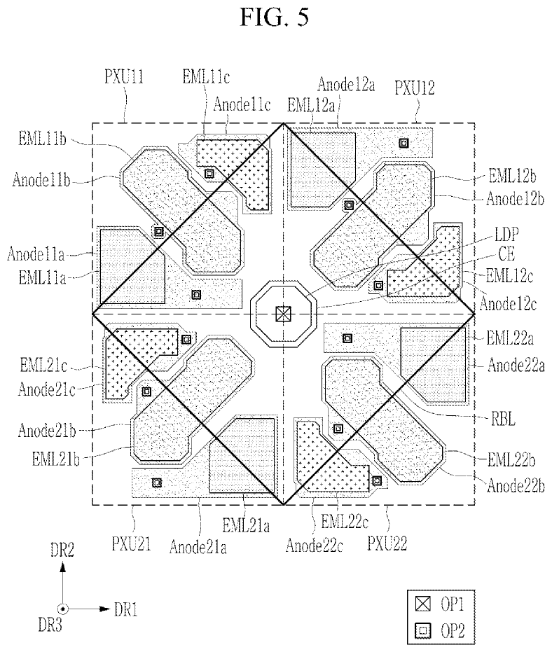

Hereinafter, modified embodiments of the embodiment of FIG. 2 will be described referring to FIGS. 5, 6, 7, and 8. FIGS. 5, 6, 7, and 8 are schematic plan views illustrating positions of light emitting devices and a laser drilling process in a light emitting display device according to an embodiment.

In the embodiment of FIG. 5, an anode opening OP2 may be added to electrically connect each anode Anode11a, Anode12a, Anode21a, Anode22a, Anode11b, Anode12b, Anode21b, Anode22b, Anode11c, Anode 12c, Anode21c, and/or Anode22c to the transistors of the pixel driving units PCa, PCb, and PCc that include each unit pixel PXU11, PXU12, PXU21, and PXU22 as shown in FIG. 2. Accordingly, the shape of the anodes Anode11a, Anode12a, Anode21a, Anode22a, Anode11b, Anode 12b, Anode21b, Anode22b, Anode11c, Anode12c, Anode21c, and/or Anode22c may be changed.

In order to arrange the glowing area or light emitting layer in a rhombus shape as shown in FIG. 1 and FIG. 2, the position of the anode opening OP2 for each unit pixel PXU11, PXU12, PXU21, and PXU22 may vary, and accordingly, the shape of each anode Anode11a, Anode12a, Anode21a, Anode22a, Anode11b, Anode 12b, Anode21b, Anode22b, Anode11c, Anode12c, Anode21c, and/or Anode22c may also be modified.

For example, the anodes Anode11b, Anode12b, Anode21b, and Anode22b disposed in the middle area of each unit pixel PXU11, PXU12, PXU21, and PXU22 may overlap the second light emitting layer EML11b, EML12b, EML21b, and EML22b in plan view and have protrusions, and the protrusions and the anode opening OP2 for the anode may overlap each other in plan view.

For example, the remaining anodes Anode11a, Anode12a, Anode21a, Anode22a, Anode11c, Anode 12c, Anode21c, and/or Anode22c may have a portion that is formed wider in plan view than the corresponding light emitting layers EML11a, EML12a, EML21a, EML22a, EML11c, EML12c, EML21c, and/or EML22c, and this portion may have a structure in which the anode opening OP2 for the anode is disposed.

The detailed structure of FIG. 5 is as follows.

Above each of the three pixel driving units PCa, PCb, and PCc included in each unit pixel PXU11, PXU12, PXU21, and PXU22, three light emitting devices may be disposed. Referring to FIG. 1 and FIG. 5, the first pixel driving unit PCa may be connected to each first anode Anode11a, Anode12a, Anode21a, and Anode22a through the anode opening OP2, and the second pixel driving unit PCb may be connected to each second anode Anode11b, Anode12b, Anode21b, and/or Anode22b through the anode opening OP2, and the third pixel driving unit PCc may be connected to each third anode Anode11c, Anode12c, Anode21c, and Anode22c through the anode opening OP2. Referring to FIG. 5, each anode Anode11a, Anode12a, Anode21a, Anode22a, Anode11b, Anode12b, Anode21b, Anode22b, Anode11c, Anode12c, Anode21c, and/or Anode22c may have a protrusion, and the protrusion may be connected to each pixel driving unit PCa, PCb, and PCc through the anode opening OP2.

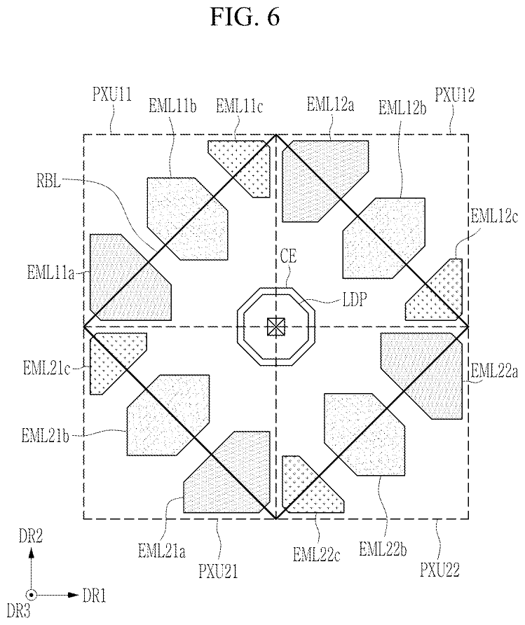

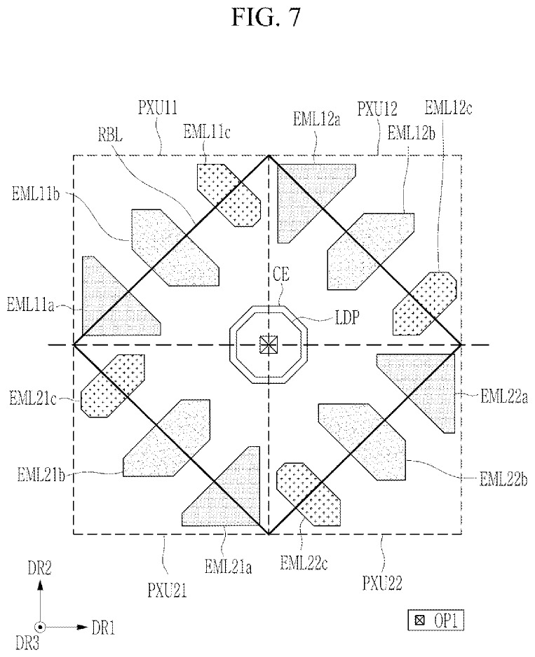

In FIG. 6 and FIG. 7, an example of a light emitting layer or light emitting region having a planar shape different from that of FIG. 2 is shown. In FIG. 6 and FIG. 7, the shape of the opening (refer to OP in module 3) disposed on the pixel defining layer (refer to 380 in FIG. 3) and the light emitting layer (EML11a, EML12a, EML21a, EML22a, EML11b, EML12b, EML21b, EML22b, EML11c, EML12c, EML21c, and/or EML22c) disposed in it are described. Unlike FIG. 2, the anode is not separately shown. For example, in FIG. 6 and FIG. 7, the position LDP where the laser drilling process is performed may be also illustrated, and an opening OP1 may overlap the connecting electrode CE disposed below the opening OP and may be electrically connected to the auxiliary low driving voltage line (refer to 174-1 of FIG. 1).

First, the embodiment of FIG. 6 will be described below.

In the embodiment of FIG. 6, the opening OP of the pixel defining layer (refer to 380 in FIG. 3) corresponding to the first light emitting layers EML11a, EML12a, EML21a, and EML22a or the first light emitting layers EML11a, EML12a, EML21a, and EML22a, the planar shape may be a triangle in which at least one corner is chamfered, and in the embodiment of FIG. 6, three corners of the triangle shape may be chamfered to have a hexagonal shape.

The planar shape of the opening OP of the pixel defining layer (refer to 380 in FIG. 3) corresponding to the second light emitting layer EML11b, EML12b, EML21b, and EML22b may be a rectangle or a hexagon with at least one corner chamfered, and in an embodiment of FIG. 6, the two opposing corners of the quadrangle shape may be chamfered to form a hexagonal shape.

The plane shape of the opening OP of the pixel defining layer corresponding to the third light emitting layer EML11c, EML12c, EML21c, and EML22c (or the plane shape of the opening OP of the third light emitting layer EML11c, EML12c, EML21c, and EML22c) may be a triangle with at least one corner chamfered, and in the embodiment of FIG. 6, the three corners of the triangle may be chamfered to form a hexagonal shape.

In the above, the first light emitting layer EML11a, EML12a, EML21a, and EML22a may display the first color light among the three primary colors of light, the second light emitting layer EML11b, EML12b, EML21b, and EML22b may display the second color light among the three primary colors of light, and the third light emitting layer EML11c, EML12c, EML21c, and EML22c may display the third color light among the three primary colors of light.

For example, the area of each light emitting layer EML11a, EML12a, EML21a, EML22a, EML11b, EML12b, EML21b, EML22b, EML11c, EML12c, EML21c, and/or EML22c, which corresponds to each color, may be formed variably considering the lifespan of the materials of the light emitting layer. For example, the area ratio shown in FIG. 6 may be variously changed.

In FIG. 7, a light emitting layer or light emitting region having a planar shape different from that of FIG. 2 and FIG. 6 is shown. In the embodiment of FIG. 7, the planar shape of the opening OP of the pixel definition layer (refer to 380 of FIG. 3) corresponding to the first light emitting layer EML11a, EML12a, EML21a, and EML22a (or the planar shape of the opening OP of the first light emitting layer EML11a, EML12a, EML21a, and EML22a) may be a triangle with at least one chamfered corner, in the embodiment of FIG. 7. For example, the corners adjacent to the dotted line area where each unit pixel PXU11, PXU12, PXU21, and PXU22 is partitioned in the triangular shape of the first light emitting layer EML11a, EML12a, EML21a, and EML22a may not be chamfered, and the remaining two corners may have a chamfered structure. As a result, the planar shape of the opening OP may have a pentagonal shape.

The planar shape of the opening OP of the pixel defining layer (refer to 380 of FIG. 3) corresponding to the second light emitting layer EML11b, EML12b, EML21b, and EML22b (or the planar shape of the opening OP of the second light emitting layer EML11b, EML12b, EML21b, and EML22b) may be a rectangle with at least one corner, which is cut off, or a hexagonal shape. In the embodiment of FIG. 6, two opposing corners of the rectangular shape may be cut off to have a hexagonal shape.

The planar shape of the opening OP of the pixel defining layer (refer to 380 of FIG. 3) corresponding to the third light emitting layer EML11c, EML12c, EML21c, and EML22c (or the planar shape of the opening OP of the third light emitting layer EML11c, EML12c, EML21c, and EML22c) may have at least one corner in the form of a square or a hexagon, and in the embodiment of FIG. 6, two opposing corners of the square shape may be rounded to form a hexagonal shape.

In the above, the first light emitting layer EML11a, EML12a, EML21a, and EML22a may display the first color light among the three primary colors of light, the second light emitting layer EML11b, EML12b, EML21b, and EML22b may display the second color light among the three primary colors of light, and the third light emitting layer EML11c, EML12c, EML21c, and EML22c may display the third color light among the three primary colors of light. For example, the area of each light emitting layer EML11a, EML12a, EML21a, EML22a, EML11b, EML12b, EML21b, EML22b, EML11c, EML12c, EML21c, and/or EML22c corresponding to each color may be formed in various ways, according to the lifespan of the materials that make up the light emitting layer. For example, the area ratio shown in FIG. 7 may be variously changed.

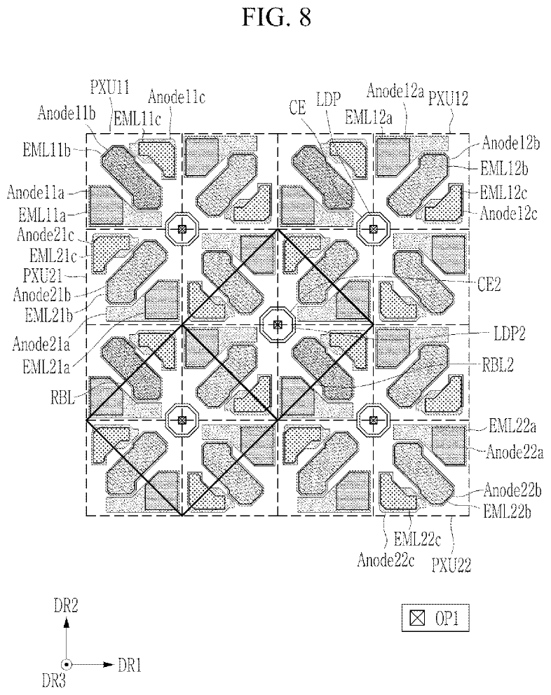

In the embodiment of FIG. 8, a position LDP2 where the laser drilling process is performed is shown at a position where edges of four adjacent unit pixel groups meet in the modified embodiment of FIG. 2. For example, the position LDP2 where laser drilling is performed may be disposed over all four unit pixel groups. For example, a connecting electrode CE2 disposed below the position LDP2 where laser drilling is performed may be formed, and an opening OP1 may be also formed to electrically connect the auxiliary low driving voltage line (refer to 174-1 of FIG. 1) below in conjunction with the connecting electrode CE2. In FIG. 8, the positions LDP for the laser drilling process and connecting electrodes CE may be formed in each unit pixel group. However, in another example, the laser drilling process may not be performed in each unit pixel group.

The detailed structure of FIG. 8 is as follows.

In FIG. 8, a total of 16 unit pixels may be arranged in a dotted line, and the 16 unit pixels may be divided into four unit pixel groups including four unit pixels each PXU11, PXU12, PXU21, and PXU22. Each unit pixel group may have four unit pixels PXU11, PXU12, PXU21, and PXU22 arranged in a 2×2 matrix. Each unit pixel group may have a rhombus-shaped arrangement RBL of light emitting devices.

In FIG. 8, at the center portion of each unit pixel group, e.g., at the position where the corners of all four unit pixels PXU11, PXU12, PXU21, and PXU22 meet, the position LDP for the laser drilling process may be disposed. For example, in FIG. 8, an opening OP1 may be formed to connect a connecting electrode (CE; also referred to as an additional connecting electrode) disposed below the position LDP where the laser drilling process is performed. The opening OP1 may overlap the connecting electrode CE to electrically connect to the auxiliary low driving voltage line (refer to 174-1 in FIG. 1).

According to an embodiment, each unit pixel group may not have the position LDP for the laser drilling process.

Four unit pixel groups having such a structure may be arranged in a 2×2 matrix, and a position LDP2 where the laser drilling process is performed may be formed at a position where the corners of all four unit pixel groups meet. For example, in FIG. 8, an opening OP1 may be provided to overlap and electrically connect a low driving voltage line (refer to 174-1 of FIG. 1) to a connecting electrode CE2 disposed below the position LDP2 where the laser drilling process is performed. In case of considering only four adjacent unit pixels disposed around the position LDP2 where the laser drilling process is performed, as shown in FIG. 8, the arrangement RBL2 of the light emitting device may have a diamond structure, and multiple light emitting layers or light emitting regions disposed on the four unit pixels adjacent to the position LDP2 where the laser drilling process is performed are also arranged in a rhombus shape.

FIG. 8 is an embodiment implemented based on the embodiment of FIG. 2, but modifications such as those of FIG. 5 to FIG. 7 may also be applied.

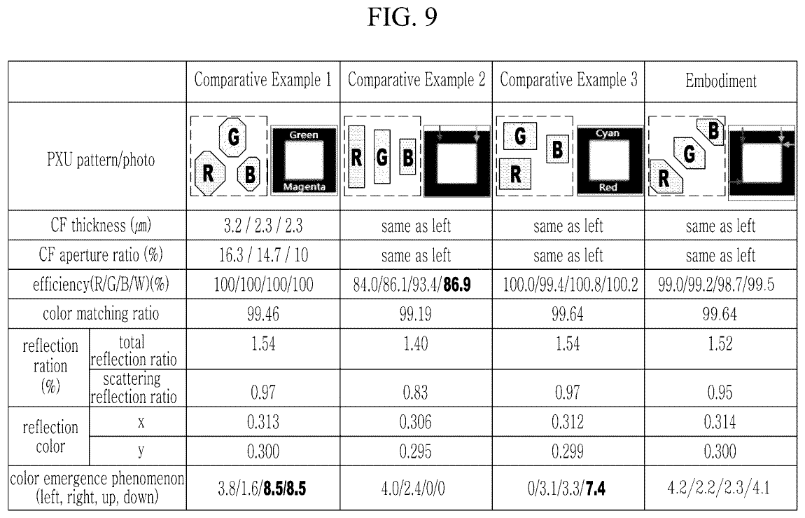

Hereinafter, based on FIG. 9, display characteristics of the embodiment of FIG. 6 and various comparative examples will be compared and described. FIG. 9 is a table comparing display characteristics according to embodiments and comparative examples. In FIG. 9, together with the embodiment of FIG. 6, the arrangement of light emitting regions within the unit pixel (PXU) of three comparative examples is shown. The three comparative examples and embodiments may be formed identically except for the arrangement of the light emitting regions. For example, the thickness of the color filters CF formed in the light emitting display device may be also formed equally, and the aperture ratios of red (R), green (G), and blue (B) may be also formed equally.

The three comparative examples and examples with the above settings have differences in color efficiency, color matching rate, reflectance, and reflected color, but they may be all included in the usable range and may not have a large difference. For example, the color coordinate values described in FIG. 9 may be values on the CIE1931 color space.

However, in terms of the color emergence phenomenon, the three comparative examples have disadvantages compared to the embodiments. The color emergence phenomenon means that a specific color may be visible at the boundary between black and white in case that white is displayed inside a black background. The color of FIG. 9 is indicated by a numerical value, and the higher the corresponding numerical value, the better the color.

In Comparative Example 1, green and magenta colors may be well visible from the top and bottom, and in Comparative Example 3, red may be well seen from the bottom, and cyan may be recognized/observed from the top.

In contrast, in the embodiment, the colors of the left and bottom are similar to each other, and the colors from the top and right may be similar to each other, but the values may not be high in each direction, so the colors may not be well visible to the user.

For example, in Comparative Example 2, the color emergence phenomenon may be less than in the Example, but in the case of forming as in Comparative Example 2, it is difficult to ascertain in case that the laser drilling process is required because a space for the laser drilling process cannot be made.

Therefore, in an embodiment, the laser drilling process may be performed even though the area that a pixel is reduced at high resolution, and the color emergence phenomenon may be improved. For example, hereinafter, unlike the above-described embodiment, an embodiment in which light emitting layers of the same color are disposed adjacent to each other will be described.

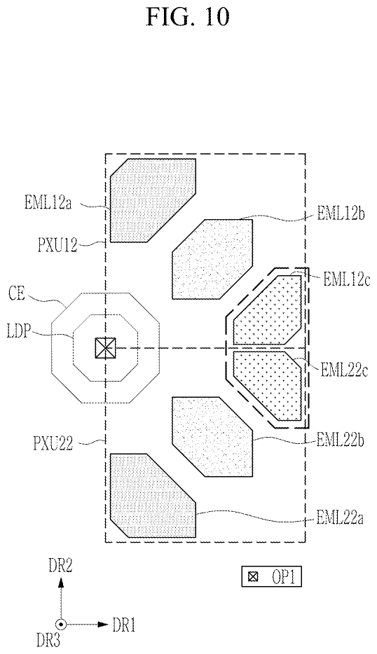

FIG. 10 is a schematic plan view illustrating a light emitting device and a position for a laser drilling process according to an embodiment. In FIG. 10, only two unit pixels PXU12 and PXU22 disposed in the right column of the unit pixel group arranged in a rhombus shape, similar to FIG. 2, are shown. For example, in FIG. 10, two light emitting layers EML12c and EML22c corresponding to the same color are disposed adjacent to each other. For example, in FIG. 10, each light emitting layer EML12a, EML12b, and EML12c of the unit pixel PXU12 may be arranged diagonally in a diagonal direction between the first direction DR1 and the opposite direction of the second direction DR2.

For example, within the area of a unit pixel PXU12, the first light emitting layer EML12a may be disposed in the upper left area, the second light emitting layer EML12b may be disposed in the middle area, and the third light emitting layer EML12c may be disposed in the lower right area. For example, each light emitting layer EML22a, EML22b, and EML22c of a fourth unit pixel PXU22 may be arranged diagonally in a diagonal direction between the opposite direction of the first direction DR1 and the opposite direction of the second direction DR2.

Also, in the area of the fourth unit pixel PXU22, the first light emitting layer EML22a may be disposed in the lower left area, the second light emitting layer EML22b may be disposed in the middle area, and the third light emitting layer EML22c may be disposed in the upper right area. As a result, in the area marked with a dotted line in FIG. 10, two adjacent unit pixels PXU12 and PXU22 may have the same color third light emitting layer EML12c and EML22c arranged adjacent to each other.

The embodiment of FIG. 10 has the following disadvantages as compared to other embodiments.

Although the embodiment of FIG. 10 is a light emitting display device for displaying high resolution, the third light emitting layers EML12c and EML22c of the same color may be adjacent to each other, so that the two third light emitting layers EML12c and EML22c may be grouped by dotted lines in FIG. 10, there is a problem in that the user recognizes the light emitting layer or the light emitting device as a relatively low-resolution image.

For example, in the embodiment of FIG. 10, the first light emitting layer EML12a and EML22a may be disposed on the left side of all unit pixels PXU12 and PXU22, and the third light emitting layer EML12c and EML22c may be positioned on the right side of all unit pixels PXU12 and PXU22. Therefore, with understanding the color emergence phenomenon of FIG. 9 with respect to the embodiment of FIG. 10, colors corresponding to the first light emitting layers EML12a and EML22a may be displayed on the left side, and colors corresponding to the third light emitting layers EML12c and EML22c may be displayed on the right side. As a result, there may be a drawback in that the color emergence phenomenon occurs relatively greatly.

Therefore, unlike the embodiment of FIG. 10, in the embodiment, the color of the light emitting layers closest to each other may be arranged between the unit pixels PXU12 and PXU22 in different colors to eliminate the problem of deterioration in resolution and to reduce the color cast and thus improve display quality. The embodiment of the light emitting display device as described above may be included in an electronic device, and the light emitting display device according to an embodiment may be used in a medium-sized electronic device such as a monitor or a television (TV). However, examples of electronic devices are not limited thereto.

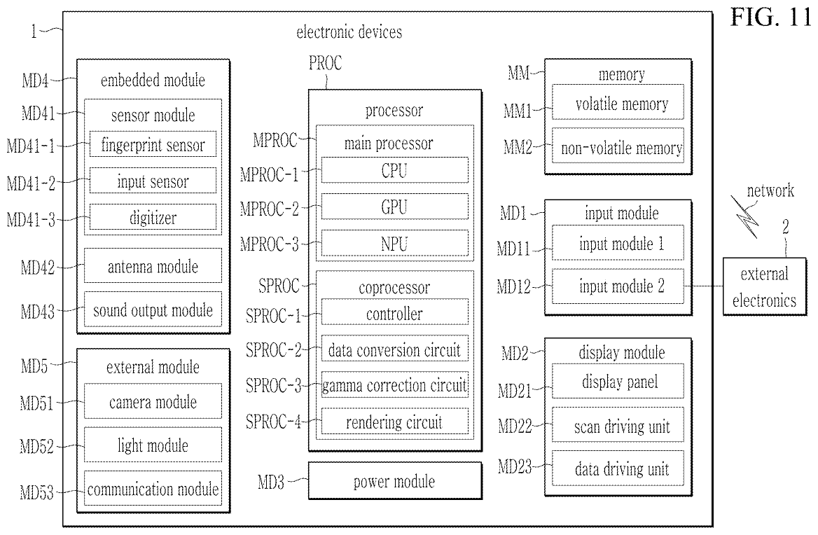

Hereinafter, an embodiment of one electronic device in which the light emitting display device according to an embodiment may be included will be described referring to FIG. 11. FIG. 11 is a schematic block diagram of an electronic device according to embodiments.

Electronic devices 1 may output various information through the display module MD2 in the operating system. In case that the processor PROC executes the application stored in the memory MM, the display module MD2 may provide the application information to the user through the display panel MD21. For example, the display panel MD21 may be used with the luminous indicator device described earlier.

The processor PROC may acquire external inputs through the input module MDI or sensor module MD41, and may execute the corresponding application for the external inputs. For example, in case that the user selects the camera icon displayed on the display panel MD21, the processor PROC may acquire user input through the input sensor MD41-2 and may activate the camera module MD51. The processor PROC may transfer video data corresponding to the captured images through the camera module MD51 to the display module MD2. The display module MD2 may display an image corresponding to the captured image through the display panel MD21.

In another example, in case that personal information authentication is performed in the display module MD2, the fingerprint sensor MD41-1 may acquire the entered fingerprint information as input data. The processor PROC may compare the input data acquired through the fingerprint sensor MD41-1 with the authentication data stored in the memory MM, and may execute the application according to the comparison result. The display module MD2 may display information that is executed according to the logic of the application through the display panel MD21.

In another example, in case that the music streaming icon displayed on the display module MD2 is selected, the processor PROC may acquire user input through the input sensor MD41-2, and may activate the music streaming application stored in the memory MM. In case that a music playback command is input into the music streaming application, the processor PROC may activate the sound output module MD43 to provide the user with audio information that corresponds to the music playback command.

In the above, the operation of the electronic device 1 was explained. Below, a detailed explanation is provided regarding the configuration of an electronic device 1. Some of the components of the aforementioned electronic device 1 may be integral with each other and provided as a single configuration, although a single configuration also is separated into two or more components and provided.

Referring to FIG. 11, the electronic device 1 may communicate with external electronic devices 2 through a network, e.g., a local wireless communication network or a long-distance wireless communication network. According to an embodiment, an electronic device 1 may include a processor PROC, memory MM, input module MD1, display module MD2, power module MD3, embedded module MD4, and external module MD5. According to an embodiment, the electronic device 1 may have at least one of the mentioned components omitted or have one or more other components added. According to an embodiment, some of the mentioned components (e.g., sensor module MD41, antenna module MD42, or sound output module MD43) may be integrated into another component (e.g., display module MD2).

The processor PROC may control at least one other component (e.g., hardware or software components) of the electronic device 1 connected to the processor PROC by executing software and may perform data processing or various calculations. According to an embodiment, the processor PROC, as at least part of data processing or computation, may store received commands or data from other components (e.g., input module MD1, sensor module MD41, or communication module MD53) in volatile memory MM1, and may process the stored commands or data in volatile memory MM1. Thus, the resulting data may be stored in non-volatile memory MM2.

A processor PROC may include a main processor MPROC and an auxiliary processor SPROC. The main processor MPROC may include one or more central processing units (MPROC-1; CPU) or application processors (AP). The main processor MPROC may also include one or more of the following: graphic processing unit (MPROC-2; GPU), communication processor (CP), and image signal processor (ISP). The main processor MPROC may also include a neural network processing device (MPROC-3; NPU). A neural network processing device may be a processor specialized in processing an artificial intelligence model, and the artificial intelligence model may be generated through machine learning. The artificial intelligence model may include artificial neural network layers. Artificial neural networks may be one of the following combinations: deep neural network (DNN), convolutional neural network (CNN), recurrent neural network (RNN), restricted Boltzmann machine (RBM), deep belief network (DBN), bidirectional recurrent deep neural network (BRDNN), deep Q-networks, or any combination of two or more of the above, but embodiments are not limited thereto. Artificial intelligence models may include software structures in addition to or instead of hardware structures. The mentioned processing unit and processor may be implemented either as a single integrated configuration (e.g., a single chip) or as separate configurations (e.g., multiple chips).

An auxiliary processor SPROC may include a controller SPROC-1. The controller SPROC-1 may include an interface conversion circuit and a timing control circuit. The controller SPROC-1 may receive video signals from the main processor MPROC and may output video data by converting the data format of the video signals according to the interface specifications with the display module MD2. The controller SPROC-1 may output various control signals necessary for driving the display module MD2. The auxiliary processor SPROC may include additional circuits such as a data conversion circuit SPROC-2, a gamma correction circuit SPROC-3, a rendering circuit SPROC-4, and so on. The data conversion circuit SPROC-2 may receive video data from the controller SPROC-1 and may compensate the video data to display the desired brightness according to the characteristics of the electronic device 1 or user settings. The data conversion circuit SPROC-2 may also convert the video data for power consumption reduction or residual compensation. The gamma correction circuit SPROC-3 may convert image data or a gamma reference voltage so that an image displayed on the electronic device 1 may have desired gamma characteristics. The rendering circuit SPROC-4 may receive video data from the controller SPROC-1 and render the video data, taking into account the pixel arrangement of the display panel MD21 applied to the electronic device 1. At least one of the data conversion circuit SPROC-2, gamma correction circuit SPROC-3, or rendering circuit SPROC-4 may be integrated into another component (e.g., the main processor MPROC or controller SPROC-1). At least one of the data conversion circuit SPROC-2, gamma correction circuit SPROC-3, and rendering circuit SPROC-4 may be integrated into the mentioned data driving unit MD23.

Memory MM may store various data used by at least one component (e.g., the processor PROC or the sensor module MD41) of the electronic device 1, as well as input data or output data related to associated commands. Memory MM may include at least one of volatile memory MM1 and non-volatile memory MM2.

The input module MD1 may receive commands or data to be used in components of an electronic device 1 (for example, processor PROC, sensor module MD41 or sound output module MD43) from outside the electronic device 1 (for example, from a user or an external electronic device 2).

The input module MD1 may include a first input module MD11 where commands or data are input from the user, and a second input module MD12 where commands or data are input from an external electronic device 2. The first input module MD11 may include a microphone, a mouse, a keyboard, keys (e.g., buttons), or a pen (e.g., a passive pen or an active pen).

The second input module MD12 may support designated protocols such that an external electronic device 2 may be connected to either through wired or wireless means. According to an embodiment, the second input module MD12 may include HDMI (high-definition multimedia interface), USB (universal serial bus) interface, SD card interface, or audio interface. The second input module MD12 may include connectors, such as HDMI connectors, USB connectors, SD card connectors, or audio connectors (e.g., headphone connectors), that are physically connected to an external electronic device 2.

The display module MD2 may visually provide information to the user. The display module MD2 may include a display panel MD21, a scan driving unit MD22, and a data driving unit MD23. The display module MD2 may include windows, chassis, and brackets to protect the display panel MD21.

The display panel MD21 may include a liquid crystal display panel, an organic light emitting display panel, or an inorganic light emitting display panel, and the types of display panels MD21 are not limited. The display panel MD21 may be either a rigid type or a flexible type that is capable of rolling or folding. The display module MD2 may also include a supporter, bracket, or heat-dissipation component that supports the display panel MD21.

The scan driving unit MD22 may be installed on the display panel MD21 as a driving chip. For example, the scan driving unit MD22 may be integrated into the display panel MD21. For example, the scan driving unit MD22 may include amorphous silicon (ASG; TFT gate driving unit circuit), low-temperature polycrystalline silicon (LTPS; TFT gate driving unit circuit), or oxide semiconductor (OSG; TFT gate driving unit circuit) integrated into the display panel MD21. The scan driving unit MD22 may receive control signals from the controller SPROC-1 and may output scan signals to the display panel MD21 in response to the control signals.

The display panel (MD21) may further include a light emitting driving unit. The light emitting driving unit may output a luminous control signal to the display panel MD21 in response to the control signal received from the controller SPROC-1. The light emitting driving unit may be formed separately from the scan driving unit MD22 or integrated into the scan driving unit MD22.

The data driving unit MD23 may receive control signals from the controller SPROC-1 and may respond to the control signals by converting video data into analog voltage (e.g., data voltage) and outputs the data voltage to the display panel MD21. The data driving unit MD23 may be integrated into other components (e.g., the controller SPROC-1). The functions of the interface conversion circuit and timing control circuit of the mentioned controller SPROC-1 may also be integrated into the data driving unit MD23.

The display module MD2 may include additional components such as a light emitting driving unit and a voltage generation circuit. The voltage generating circuit may output various voltages necessary for driving the display panel MD21. The power module MD3 may supply power to components of the electronic device 1. The power module MD3 may include a battery charging the power voltage. The battery may include a non-rechargeable primary cell, a rechargeable secondary cell, or a fuel cell.

The power module MD3 may include a power management integrated circuit (PMIC). The PMIC supplies optimized power to each of the above-described modules and modules described later.

The power module MD3 may include a wireless power transmission/reception part electrically connected to the battery. The wireless power transmission/reception part may include antenna radiators in the form of coils. Electronic devices may include both built-in modules MD4 and external modules MD5. The embedded module MD4 may include the sensor module MD41, the antenna module MD42, and the sound output module MD43. The external module MD5 may include the camera module MD51, the light module MD52, and the communication module MD53.

The sensor module MD41 may detect inputs from the user's body or inputs from a pen on the first input module MD11, and may generate corresponding electrical signals or data values for the inputs. The sensor module MD41 may include at least one or more of the fingerprint sensor MD41-1, input sensor MD41-2, and digitizer MD41-3.

The fingerprint sensor MD41-1 may generate a data value corresponding to the user's fingerprint. The fingerprint sensor MD41-1 may include either an optical or a capacitive fingerprint sensor.

The input sensor MD41-2 may generate data values corresponding to coordinate information of the user's body input or pen input. The input sensor MD41-2 may generate the amount of change in capacitance by the input as a data value. The input sensor MD41-2 may detect an input by a passive pen or transmit/receive data to/from an active pen. The input sensor MD41-2 may measure bio-signals such as blood pressure, moisture, or body fat. For example, in case that the user touches a part of his or her body to the sensor layer or sensing panel and does not move for a certain period of time, the input sensor MD41-2 may detect the biological signal based on the changes in the electrical field caused by the body part, and may output the desired information of the user to the display module MD2.

The digitizer MD41-3 may generate data values corresponding to the coordinate information input by the active pen. The digitizer MD41-3 may generate data values based on changes in electronic quantities input by the active pen. The digitizer MD41-3 may detect input from a passive pen or transmit and receive data with an active pen.

At least one of the fingerprint sensor MD41-1, input sensor MD41-2, and digitizer MD41-3 may be implemented as a sensor layer formed on the display panel MD21 through a continuous process. The fingerprint sensor MD41-1, input sensor MD41-2, and digitizer MD41-3 may be placed on the upper side of the display panel MD21, and one of the fingerprint sensor MD41-1, input sensor MD41-2, and digitizer MD41-3 (e.g., the digitizer MD41-3) may be placed on the lower side of the display panel MD21.

At least two or more of the fingerprint sensor MD41-1, input sensor MD41-2, and digitizer MD41-3 may be integrated into a single sensing panel through the same process. In case that they are integrated into a single sensing panel, the sensing panel may be placed between the display panel MD21 and the window placed on the upper side of the display panel MD21. According to an embodiment, the sensing panel may be disposed on the window, and the position of the sensing panel is not limited.

At least one of the fingerprint sensor MD41-1, input sensor MD41-2, and digitizer MD41-3 may be integrated into the display panel MD21. For example, through the process of forming components (e.g., light emitting devices, or transistors) included in the display panel MD21, at least one of the fingerprint sensor MD41-1, input sensor MD41-2, and digitizer MD41-3 may be formed simultaneously.

For example, the sensor module MD41 may generate electrical signals or data values corresponding to the internal or external conditions of the electronic device 1. The sensor module MD41 may be, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor, and a sensor may be further included.

The antenna module MD42 may include one or more antennas for transmitting signals or power to the outside or receiving signals or power from the outside. According to an embodiment, the communication module MD53 may transmit a signal to an external electronic device or receive a signal from an external electronic device through an antenna suitable for a communication method. The antenna pattern of the antenna module MD42 may be integrated into one component of the display module MD2 (e.g., the display panel MD21) or the input sensor MD41-2.

The sound output module MD43 may be a device used to output audio signals to the outside of the electronic device 1. For example, the sound output module MD43 may include speakers used for general purposes such as multimedia playback or recording playback, as well as receivers used exclusively for telephone reception. According to an embodiment, the receiver may be integral with or separately from the speaker. The sound output pattern of the sound output module MD43 may also be integrated into the display module MD2.

The camera module MD51 may capture still images and moving images. According to an embodiment, the camera module MD51 may include one or more lenses, image sensors, or image signal processors. The camera module MD51 may further include an infrared camera capable of measuring the presence or absence of a user, the user's position, and the user's line of sight view.

The light module MD52 may provide light. The light module MD52 may include light-emitting diodes or xenon lamps. The light module MD52 may operate in conjunction with the camera module MD51 or independently.

The communication module MD53 may support the establishment of wired or wireless communication channels between electronic devices 1 and external electronic devices 2, as well as communication performance through the established communication channels. The communication module MD53 may include one or all of the wireless communication modules such as cellular communication module, short-range wireless communication module, or global navigation satellite system (GNSS) communication module, and wired communication modules such as local area network (LAN) communication module or power line communication module. The communication module MD53 may communicate with external electronic devices 2 through short-range communication networks such as Bluetooth, WiFi Direct, or infrared data association (IrDA), or through long-range communication networks such as cellular networks, the internet, or computer networks (e.g., LAN or WAN). Various types of communication modules MD53 described above may be implemented either as a single chip or as separate chips. Input module MD1, sensor module MD41, camera module MD51, etc. may be used to control the operation of the display module MD2 by interfacing with the processor PROC.

The processor PROC may output commands or data to the display module MD2, sound output module MD43, camera module MD51, or light module MD52 based on the input data received from the input module MD1. For example, the processor PROC may generate video data in response to input data generated through a mouse or an active pen and output the video data to a display module MD2, or the processor PROC may generate command data in response to input data and output the command data to a camera module MD51 or a light module MD52. In case that the processor PROC does not receive input data for a certain period of time from the input module MD1, the operating mode of the electronic device I may be changed to low-power mode or sleep mode, thereby reducing the power consumption of the electronic device 1.

The processor PROC may output commands or data to the display module MD2, sound output module MD43, camera module MD51, or light module MD52 based on the sensing data received from the sensor module MD41. For example, the processor PROC may execute the application based on the comparison result between the authorized authentication data authorized by the fingerprint sensor MD41-1 and the authentication data stored in the memory MM. The processor PROC may execute commands or display video data in response to sensing data detected by the input sensor MD41-2 or digitizer MD41-3 on the display module MD2. In case that the temperature sensor is included in the sensor module MD41, the processor PROC may receive temperature data for the measured temperature from the sensor module MD41 and perform brightness correction for image data based on the temperature data.

The processor PROC may receive measurement data about the presence of the user, the user's position, and the user's gaze from the camera module MD51. The processor PROC may perform luminance correction and other adjustments to image data based on measured data. For example, the processor PROC that determines the presence of a user through input from the camera module MD51 may output brightness-corrected image data to the display module MD2 through data conversion circuit SPROC-2 or gamma correction circuit SPROC-3.

Some of the above components may be connected to each other through communication methods between peripheral devices, such as bus, general purpose input/output (GPIO), serial peripheral interface (SPI), mobile industry processor interface (MIPI), or ultra path interconnect (UPI) links, in order to exchange signals (e.g., commands or data) between each other. The processor PROC may communicate with the display module MD2 through a mutually agreed interface, and for example, may utilize any of the mentioned communication methods without being limited to the mentioned communication methods.

The electronic device 1 according to various embodiments disclosed in this document may be various types of devices. The electronic device 1 may include, for example, at least one of a portable communication device (e.g., a smart phone), a computer device, a portable multimedia device, a portable medical device, a camera, a wearable device, and a home appliance. The electronic device 1 according to an embodiment of this document is not limited to the aforementioned devices.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A light emitting display device comprising:
a unit pixel group including a first unit pixel, a second unit pixel, a third unit pixel, and a fourth unit pixel that are arranged in a 2×2 matrix shape in a first direction and a second direction that are perpendicular to each other, wherein
each of the first, second, third, and fourth unit pixels includes a first light emitting region, a second light emitting region, and a third light emitting region that emit lights of three primary colors, respectively,
the first light emitting region, the second light emitting region, and the third light emitting region of the first unit pixel are sequentially arranged in a first diagonal direction with respect to the first and second directions,
the first light emitting region, the second light emitting region, and the third light emitting region of the second unit pixel are sequentially arranged in a second diagonal direction, and
the first light emitting region, the second light emitting region, and the third light emitting region of the third unit pixel are sequentially arranged in a third diagonal direction, and
the first light emitting region, the second light emitting region, and the third light emitting region of the fourth unit pixel are sequentially arranged in a fourth diagonal direction,
the first diagonal direction, the second diagonal direction, and the third diagonal direction, and the fourth diagonal direction form a rhombus shape, and
a position where a laser drilling process is performed is a center portion of the unit pixel group.

2. The light emitting display device of claim 1, wherein:
the second diagonal direction is symmetrical to the first diagonal direction with respect to the second direction,
the third diagonal direction is symmetrical to the first diagonal direction with respect to the first direction, and
the fourth diagonal direction is parallel to the first diagonal direction and opposite to the first diagonal direction.

3. The light emitting display device of claim 2, wherein:
a first virtual line extends in the first diagonal direction and diagonally connects corner portions of the first unit pixel,
a second virtual line extends in the second diagonal direction and diagonally connects corner portions of the second unit pixel,
a third virtual line extends in the third diagonal direction and diagonally connects corner portions of the third unit pixel,
a fourth virtual line extends in the fourth diagonal direction and diagonally connects corner portions of the fourth unit pixel, and
the first virtual line, the second virtual line, the third virtual line, and the fourth virtual line form the rhombus shape.

4. The light emitting display device of claim 3, wherein
the first light emitting region of the first unit pixel is adjacent to the third light emitting region of the second unit pixel,
the third light emitting region of the first unit pixel is adjacent to the first light emitting region of the third unit pixel,
the third light emitting region of the third unit pixel is adjacent to the first light emitting region of the fourth unit pixel, and
the third light emitting region of the fourth unit pixel is adjacent to the first light emitting region of the second unit pixel.

5. The light emitting display device of claim 2, wherein
the second unit pixel is adjacent to the first unit pixel along the second direction,
the third unit pixel is adjacent to the first unit pixel along the first direction, and
the fourth unit pixel is adjacent to the first unit pixel in a diagonal direction.

6. The light emitting display device of claim 1, wherein
a connecting electrode is disposed at the center portion of the unit pixel group.

7. The light emitting display device of claim 6, comprising:
a pixel defining layer having openings corresponding to the first light emitting region, the second light emitting region, and the third light emitting region;
an anode overlapping a portion of the opening of the pixel defining layer in plan view;
a light emitting layer on the anode and disposed in the opening of the pixel defining layer; and
a cathode disposed on the pixel defining layer and the light emitting layer, wherein
the connecting electrode is electrically connected to the cathode by the laser drilling process.

8. The light emitting display device of claim 7, wherein
the connecting electrode and the anode are formed of a same material and are disposed on a same layer.

9. The light emitting display device of claim 7, further comprising:
a low driving voltage line and an auxiliary low driving voltage line disposed on different insulating layers and having different extension directions, wherein
the low driving voltage line and the auxiliary low driving voltage line transfer a low driving voltage transmitted to the cathode, and
the connecting electrode is electrically connected to the auxiliary low driving voltage line.

10. A light emitting display device comprising:
first, second, third, and fourth unit pixel groups arranged in a 2×2 matrix shape in a first direction and a second direction that are perpendicular to each other, wherein
each of the first, second, third, and fourth unit pixel groups includes a first unit pixel, a second unit pixel, a third unit pixel, and a fourth unit pixel that are arranged in a 2×2 matrix shape,
each of the first, second, third, and fourth unit pixels includes a first light emitting region, a second light emitting region, and a third light emitting region that emit lights of three primary colors,
a position where a laser drilling process is performed corresponds to a position where corner portions of the first, second, third, and fourth unit pixel groups meet, and
areas where the laser drilling process is performed are disposed in all of the first, second, third, and fourth unit pixel groups.

11. The light emitting display device of claim 10, wherein
the first light emitting region, the second light emitting region, and the third light emitting region of each of the first, second, third, and fourth unit pixels where the laser drilling process is performed are arranged in a rhombus shape.

12. The light emitting display device of claim 11, wherein:
each of the first, second, third, and fourth unit pixel groups includes a first unit pixel, a second unit pixel, a third unit pixel, and a fourth unit pixel;
the first light emitting region, the second light emitting region, and the third light emitting region of the first unit pixel are sequentially arranged in a first diagonal direction with respect to a first direction and a second direction,
the first light emitting region, the second light emitting region, and the third light emitting region of the second unit pixel are sequentially arranged in a second diagonal direction,
the first light emitting region, the second light emitting region and the third light emitting region of the third unit pixel are sequentially arranged in a third diagonal direction,
the first light emitting region, the second light emitting region, and the third light emitting region of the fourth unit pixel are sequentially arranged in a fourth diagonal direction; and
the first diagonal direction, the second diagonal direction, the third diagonal direction, and the fourth diagonal direction form a rhombus shape.

13. The light emitting display device of claim 12, wherein:
the second diagonal direction is symmetrical to the first diagonal direction with respect to the second direction,
the third diagonal direction is symmetrical to the first diagonal direction with respect to the first direction, and
the fourth diagonal direction is parallel to the first diagonal direction and opposite to the first diagonal direction.

14. The light emitting display device of claim 13, wherein:
a first virtual line extends in the first diagonal direction and diagonally connects corner portions of the first unit pixel,
a second virtual line extends in the second diagonal direction and diagonally connects corner portions of the second unit pixel,
a third virtual line extends in the third diagonal direction and diagonally connects corner portions of the third unit pixel,
a fourth virtual line extends in the fourth diagonal direction and diagonally connects corner portions of the fourth unit pixel, and
the first virtual line, the second virtual line, the third virtual line, and the fourth virtual line form the rhombus shape.

15. The light emitting display device of claim 14, wherein:
the first light emitting region of the first unit pixel is adjacent to the third light emitting region of the second unit pixel,
the third light emitting region of the first unit pixel is adjacent to the first light emitting region of the third unit pixel,
the third light emitting region of the third unit pixel is adjacent to the first light emitting region of the fourth unit pixel, and
the third light emitting region of the fourth unit pixel is adjacent to the first light emitting region of the second unit pixel.

16. The light emitting display device of claim 13, wherein:
the second unit pixel is adjacent to the first unit pixel along the second direction,
the third unit pixel is adjacent to the first unit pixel along the first direction, and
the fourth unit pixel is adjacent to the first unit pixel in a diagonal direction.

17. The light emitting display device of claim 10, wherein
a connecting electrode is disposed at a position where corners of the first, second, third, and fourth unit pixel groups meet.

18. The light emitting display device of claim 17, comprising:
a pixel defining layer having openings corresponding to the first light emitting region, the second light emitting region, and the third light emitting region;
an anode overlapping a portion of the opening of the pixel defining layer in plan view;
a light emitting layer on the anode and disposed in the opening of the pixel defining layer; and
a cathode disposed on the pixel defining layer and the light emitting layer, wherein
the connecting electrode is electrically connected to the cathode by the laser drilling process; and
the connecting electrode and the anode are made of a same material and disposed on a same layer.

19. The light emitting display device of claim 18, further comprising:
a low driving voltage line and an auxiliary low driving voltage line disposed on different insulating layers and having different extension directions;
the low driving voltage line and the auxiliary low driving voltage line transfer a low driving voltage transmitted to the cathode; and
the connecting electrode is electrically connected to the auxiliary low driving voltage line.

20. The light emitting display device of claim 18, wherein:
an additional connecting electrode is disposed at the center portion of the unit pixel group, and
the additional connecting electrode and the anode are made of a same material and disposed on a same layer.
